(19) United States
(12) Patent Application Publication
(10) Pub. No.: US 2026/0353861 A1
(43) Pub. Date: Nov. 5, 2026

(54) MICRO-LED DEVICES AND METHODS FOR PRODUCING THE SAME

(71) Applicant: Applied Materials, Inc., Santa Clara, CA (US)

(72) Inventors: Kai DING, Cupertino, CA (US); Mingwei ZHU, San Jose, CA (US); Lisong XU, Santa Clara, CA (US); Peiwen LIU, Fremont, CA (US); Yudan GUO, Santa Clara, CA (US); Haoxiong YAN, Santa Clara, CA (US); Hyunsung BANG, Sunnyvale, CA (US); Jeff FRANKLIN, Santa Clara, CA (US); Jianfeng SUN, Milpitas, CA (US); Cong CHEN, Cupertino, CA (US); Kulandaivelu SIVANANDAN, Santa Clara, CA (US); Yongwook KIM, Sunnyvale, CA (US); Hou T. NG, Campbell, CA (US); Nag PATIBANDLA, Santa Clara, CA (US)

(21) Appl. No.: 19/661,162

(22) Filed: Apr. 28, 2026

Related U.S. Application Data
(60) Provisional application No. 63/797,925, filed on Apr. 30, 2025.

(51) Int. Cl. H10H 20/01; H10H 20/812; H10H 20/819

(52) U.S. Cl. CPC H10H 20/0137; H10H 20/812; H10H 20/819

(57) ABSTRACT

Embodiments of the present disclosure generally relate to the field of microelectronic devices, more particularly, to light emitting diode (LED) devices and methods of fabricating the same. In one or more embodiments, a micro-LED device contains a gallium nitride support layer disposed on the substrate, an n-doped gallium nitride layer, a quantum well region containing alternating layers of indium gallium nitride wells and gallium nitride barriers, and a p-doped gallium nitride layer disposed on the quantum well region. The micro-LED device also contains a first mesa structure, a TCO layer disposed on the p-doped gallium nitride layer, and a second mesa structure. The micro-LED device further contains a dielectric passivation layer disposed on portions of the mesa structures, a p-contact layer disposed on the revealed portion of the TCO layer, and an n-contact layer disposed on the revealed portion of the n-doped gallium nitride layer.

### CROSS-REFERENCE TO RELATED APPLICATIONS

This application claims benefit to U.S. Prov. Appl. No. 63/797,925, filed on Apr. 30, 2025, which is hereby incorporated by reference in its entirety herein.

### BACKGROUND

### Field

Embodiments of the present disclosure generally relate to the field of microelectronic devices and manufacturing processes thereof, more particularly, to light emitting diode (LED) devices and methods of producing the LED devices including micro-LED devices.

### Description of the Related Art

Modulation bandwidth of conventional LEDs is in the range of a few hundred MHz to about 1 GHz or slightly greater than 1 GHz, while energy efficient photonic interconnects need faster speed. As LED die size shrinks, the light output power (LOP) decreases, which causes reduced signal to noise ratio in data communication and increased bit error rate (BER).

Therefore, there is a need for improved LED devices, including micro-LED devices, and methods for producing such LED devices.

### BRIEF DESCRIPTION OF THE DRAWINGS

Implementations of the present disclosure, briefly summarized above and discussed in greater detail below, can be understood by reference to the illustrative implementations of the disclosure depicted in the appended drawings. It is to be noted, however, that the appended drawings illustrate only typical implementations of this disclosure and are therefore not to be considered limiting of its scope, for the disclosure may admit to other equally effective implementations.

FIG. 1 is a flowchart which includes a method or flow process for producing a micro-LED (light emitting diode) device, according to one or more embodiments described and discussed herein.

FIGS. 2A-2F depict a cross-sectional view of a workpiece containing a substrate at different time intervals passing through a flow process for manufacturing, forming, or otherwise producing a micro-LED device with coaxial contacts, such as the method or flow process illustrated in FIG. 1, according to one or more embodiments described and discussed herein.

FIG. 3 is a flowchart which includes a method or flow process for producing a micro-LED device containing ion-doped materials, according to one or more embodiments described and discussed herein.

FIGS. 4A-4G depict a cross-sectional view of a workpiece containing a substrate at different time intervals passing through a flow process for manufacturing, forming, or otherwise producing a micro-LED device with coaxial contacts, such as the method or flow process illustrated in FIG. 3, according to one or more embodiments described and discussed herein.

FIGS. 5A-5B depict a cross-sectional view and a top view of a micro-LED device with coaxial contacts, according to one or more embodiments described and discussed herein.

FIGS. 6A-6B depict a cross-sectional view and a top view of another micro-LED device with coaxial contacts, according to one or more embodiments described and discussed herein.

FIGS. 7A-7B depict a cross-sectional view and a top view of another micro-LED device with coaxial contacts, according to one or more embodiments described and discussed herein.

FIGS. 8A-8B depict a cross-sectional view and a top view of another micro-LED device with coaxial contacts, according to one or more embodiments described and discussed herein.

FIG. 9 is a flowchart which includes a method or flow process for producing a micro-LED device, according to one or more embodiments described and discussed herein.

FIGS. 10A-10H depict a cross-sectional view of a workpiece containing a substrate at different time intervals passing through a flow process for manufacturing, forming, or otherwise producing a micro-LED device, such as the method or flow process illustrated in FIG. 9, according to one or more embodiments described and discussed herein.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### SUMMARY

Embodiments of the present disclosure generally relate to the field of microelectronic devices and manufacturing processes thereof, more particularly, to light emitting diode (LED) devices (including micro-LED devices) and methods of fabricating, manufacturing, preparing, making, or otherwise producing such LED devices. Embodiments described and discussed herein provide micro-LED devices which have achieved high −3 dB modulation bandwidths greater than 1 GHz and under current densities of smaller than 5 kA/cm². In some embodiments, the micro-LED devices may contain a p-contact and an n-contact which are coaxial with each other. In some examples, the p-contact has a circular geometry, the n-contact layer has a ring geometry, and the n-contact encompasses the p-contact.

In one or more embodiments, a micro-LED device is provided and contains a layered stack disposed on a substrate, the layered stack contains a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers; and a p-doped gallium nitride layer disposed on the quantum well region. The micro-LED device also contains a first mesa structure containing at least a first portion of the layered stack, at least the p-doped gallium nitride layer, the quantum well region, and an upper portion of the n-doped gallium nitride layer form the first mesa structure. The micro-LED device also contains a transparent conductive oxide (TCO) layer disposed on at least a portion of the p-doped gallium nitride layer. The micro-LED device further contains a second mesa structure containing at least a second portion of the layered stack, at least a lower portion of the n-doped gallium nitride layer and the gallium nitride support layer form the second mesa structure. The micro-LED device also contains a dielectric passivation layer disposed on a first portion of the first mesa structure and a first portion of the second mesa structure, a revealed portion of the TCO layer in the first mesa structure is free or substantially free of the dielectric passivation layer, a revealed portion of the n-doped gallium nitride layer in the second mesa structure is free or substantially free of the dielectric passivation layer, and a p-contact layer disposed on the revealed portion of the TCO layer and an n-contact layer disposed on the revealed portion of the n-doped gallium nitride layer. In one or more examples, the p-contact layer has a circular geometry, the n-contact layer has a ring geometry, and the n-contact layer is coaxial to and encompasses the p-contact layer.

In other embodiments, a method for producing a micro-LED device is provided and includes depositing a layered stack disposed on a substrate, the layered stack contains: a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers, and a p-doped gallium nitride layer disposed on the quantum well region. The method also includes forming a first mesa structure from at least a first portion of the layered stack during a first mesa etch process, at least the p-doped gallium nitride layer, the quantum well region, and an upper portion of the n-doped gallium nitride layer are etched away to form the first mesa structure. The method further includes depositing a TCO layer on at least a portion of the p-doped gallium nitride layer during a TCO deposition process, and forming a second mesa structure from at least a second portion of the layered stack during a second mesa etch process, at least a lower portion of the n-doped gallium nitride layer and the gallium nitride support layer are etched away to form the second mesa structure. The method also includes depositing a dielectric passivation layer on the first and second mesa structures during a passivation layer deposition process, revealing at least a portion of the TCO layer in the first mesa structure to form a revealed portion of the TCO layer and revealing at least a portion of the n-doped gallium nitride layer in the second mesa structure to form a revealed portion of the n-doped gallium nitride layer, and depositing a p-contact layer on the revealed portion of the TCO layer and an n-contact layer on the revealed portion of the n-doped gallium nitride layer.

In some embodiments, a micro-LED device is provided and contains a layered stack disposed on a substrate, the layered stack contains a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers, and a p-doped gallium nitride layer disposed on the quantum well region. The micro-LED device also contains a first mesa structure containing at least a first portion of the layered stack, at least the p-doped gallium nitride layer, the quantum well region, and an upper portion of the n-doped gallium nitride layer form the first mesa structure, outside surfaces and at least a portion of an upper surface of the first mesa structure contains implanted comprise an ion-doped portion of the first mesa structure, and where the ion-doped portion contains one or more elemental ions selected from hydrogen, helium, boron, carbon, nitrogen, oxygen, fluorine, silicon, phosphorus, argon, chromium, iron, zinc, titanium, or any combination thereof. The micro-LED device also contains a TCO layer disposed on at least a portion of the p-doped gallium nitride layer. The micro-LED device further contains a second mesa structure containing at least a second portion of the layered stack, at least a lower portion of the n-doped gallium nitride layer and the gallium nitride support layer form the second mesa structure. The micro-LED device also contains a dielectric passivation layer disposed on a first portion of the first mesa structure and a first portion of the second mesa structure, a revealed portion of the TCO layer in the first mesa structure is free or substantially free of the dielectric passivation layer, a revealed portion of the n-doped gallium nitride layer in the second mesa structure is free or substantially free of the dielectric passivation layer, and a p-contact layer disposed on the revealed portion of the TCO layer and an n-contact layer disposed on the revealed portion of the n-doped gallium nitride layer.

In one or more embodiments, a method for producing a micro-LED device is provided and includes depositing a layered stack disposed on a substrate, the layered stack contains a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers, and a p-doped gallium nitride layer disposed on the quantum well region. The method also includes forming a first mesa structure from at least a first portion of the layered stack during a first mesa etch process, at least the p-doped gallium nitride layer, the quantum well region, and an upper portion of the n-doped gallium nitride layer are etched away to form the first mesa structure. The method further includes exposing side surfaces and at least a portion of an upper surface of the first mesa structure to an ion implantation process to produce ion-doped portion of the first mesa structure and depositing a TCO layer on at least a portion of the p-doped gallium nitride layer during a TCO deposition process. The method also includes forming a second mesa structure from at least a second portion of the layered stack during a second mesa etch process, at least a lower portion of the n-doped gallium nitride layer and the gallium nitride support layer are etched away to form the second mesa structure. The method further includes depositing a dielectric passivation layer on the first and second mesa structures during a passivation layer deposition process, revealing at least a portion of the TCO layer in the first mesa structure to form a revealed portion of the TCO layer and revealing at least a portion of the n-doped gallium nitride layer in the second mesa structure to form a revealed portion of the n-doped gallium nitride layer, and depositing a p-contact layer on the revealed portion of the TCO layer and an n-contact layer on the revealed portion of the n-doped gallium nitride layer.

In some embodiments, a micro-LED device is provided and contains a layered stack disposed on a substrate, the layered stack contains a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers, and a p-doped gallium nitride layer disposed on the quantum well region.

The micro-LED device also contains a first mesa structure containing at least a first portion of the layered stack, at least the p-doped gallium nitride layer, the quantum well region, and an upper portion of the n-doped gallium nitride layer form the first mesa structure. The micro-LED device further contains a TCO layer disposed on at least a portion of the p-doped gallium nitride layer, a second mesa structure containing at least a second portion of the layered stack, at least a lower portion of the n-doped gallium nitride layer and the gallium nitride support layer form the second mesa structure, and a first dielectric passivation layer disposed on a first portion of the first mesa structure and a first portion of the second mesa structure. The micro-LED device also contains a revealed portion of the TCO layer in the first mesa structure is free or substantially free of the first dielectric passivation layer, a revealed portion of the n-doped gallium nitride layer in the second mesa structure is free or substantially free of the first dielectric passivation layer, and a p-contact layer disposed on the revealed portion of the TCO layer and an n-contact layer disposed on the revealed portion of the n-doped gallium nitride layer. The micro-LED device further contains a second dielectric passivation layer disposed on the first and second mesa structures, a revealed portion of the p-contact layer in the first mesa structure is free or substantially free of the second dielectric passivation layer, and a revealed portion of the n-contact layer in the second mesa structure is free or substantially free of the second dielectric passivation layer. The micro-LED device also contains a p-bonding pad disposed on the revealed portion of the p-contact layer and a first portion of the second dielectric passivation layer and an n-bonding pad disposed on the revealed portion of the n-contact layer and a second portion of the second dielectric passivation layer.

In one or more embodiments, a method for producing a micro-LED device is provided and includes depositing a layered stack disposed on a substrate, the layered stack contains a gallium nitride support layer disposed on the substrate, an n-doped gallium nitride layer disposed on the gallium nitride support layer, a quantum well region disposed on the n-doped gallium nitride layer, the quantum well region contains alternating layers of indium gallium nitride wells and gallium nitride barriers, and a p-doped gallium nitride layer disposed on the quantum well region. The method also includes forming a first mesa structure from at least a first portion of the layered stack during a first mesa etch process, at least the p-doped gallium nitride layer, the quantum well region, and an upper portion of the n-doped gallium nitride layer are etched away to form the first mesa structure. The method further includes depositing a TCO layer on at least a portion of the p-doped gallium nitride layer during a TCO deposition process and forming a second mesa structure from at least a second portion of the layered stack during a second mesa etch process, at least a lower portion of the n-doped gallium nitride layer and the gallium nitride support layer are etched away to form the second mesa structure. The method also includes depositing a first dielectric passivation layer on the first and second mesa structures during a first passivation layer deposition process, revealing at least a portion of the TCO layer in the first mesa structure and at least a portion of the n-doped gallium nitride layer in the second mesa structure, and depositing a p-contact layer on the revealed portion of the TCO layer and an n-contact layer on the revealed portion of the n-doped gallium nitride layer. The method further includes depositing a second dielectric passivation layer on the first and second mesa structures during a second passivation layer deposition process, revealing at least a portion of the p-contact layer and at least a portion of the n-contact layer, and depositing a p-bonding pad on the revealed portion of the p-contact layer and a first portion of the second dielectric passivation layer and depositing an n-bonding pad on the revealed portion of the n-contact layer and a second portion of the second dielectric passivation layer.

### DETAILED DESCRIPTION

Embodiments of the present disclosure generally relate to the field of microelectronic devices and manufacturing processes thereof, more particularly, to light emitting diode (LED) devices (including micro-LED devices) and methods of fabricating, manufacturing, preparing, making, or otherwise producing such LED devices. Embodiments described and discussed herein provide micro-LED devices which have achieved high −3 dB modulation bandwidths greater than 1 GHz and under current densities of smaller than 5 kA/cm². In some embodiments, the micro-LED devices may contain a p-contact and an n-contact which are coaxial with each other. In some examples, the p-contact has a circular geometry, the n-contact has a ring geometry, and the n-contact encompasses the p-contact.

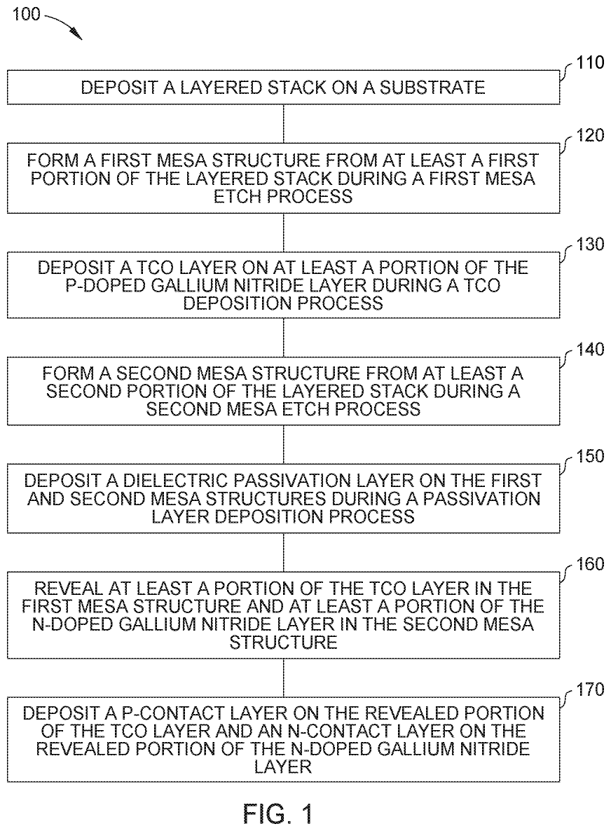

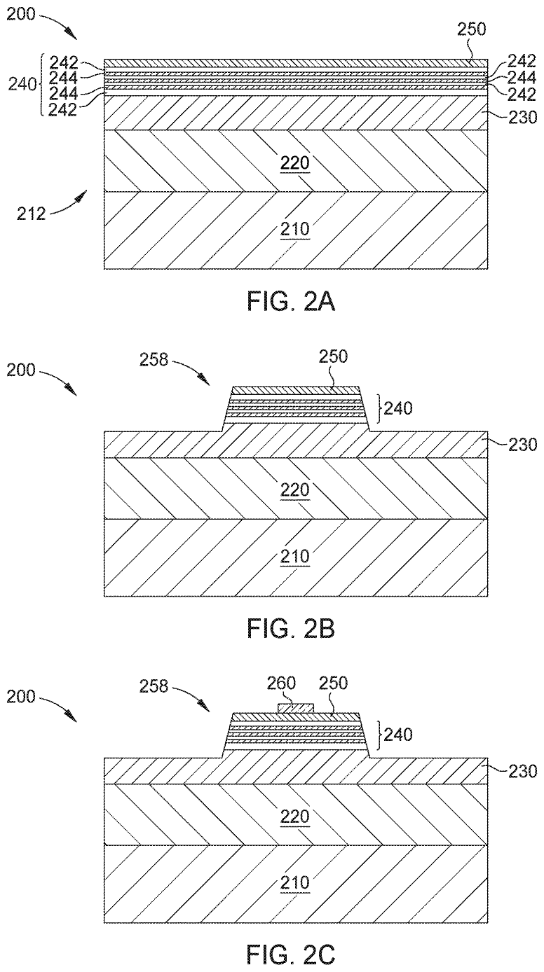

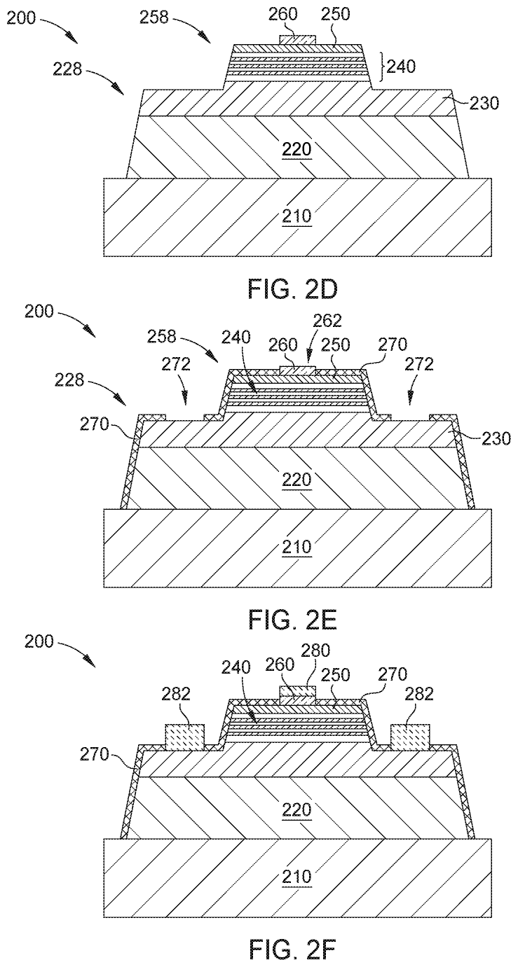

FIG. 1 is a flowchart which includes a method 100 (e.g., flow process) for producing a micro-LED device, according to one or more embodiments described and discussed herein. The method 100 includes operations 110-170, as further described and discussed below. FIGS. 2A-2F depict a cross-sectional view of a workpiece (e.g., micro-LED device) 200 at different time intervals passing through a flow process for manufacturing, forming, or otherwise producing one or more different types of micro-LED devices with coaxial contacts, the flow process may be such as the method 100 illustrated in FIG. 1, according to one or more embodiments described and discussed herein. The method 100, and variations thereof, may also be followed to produce other type of micro-LED devices, shown and not shown, in embodiments described and discussed herein.

In one or more embodiments, the method 100 for producing micro-LED devices at operation 110, illustrated in FIG. 1, is provided and includes depositing a layered stack 212 on a substrate 210, as depicted by the workpiece 200 in FIG. 2A. The layered stack 212 may contain a gallium nitride support layer 220 disposed on the substrate 210, an n-doped gallium nitride layer 230 disposed on the gallium nitride support layer 220, a quantum well region 240 disposed on the n-doped gallium nitride layer 230. A p-doped gallium nitride layer 250 may be deposited or otherwise disposed on the quantum well region 240. The quantum well region 240 contains alternating layers of indium gallium nitride wells 242 and gallium nitride barriers 244. The method 100 at operation 120 also includes forming a first mesa structure 258 from at least a first portion of the layered stack 212 during a first mesa etch process, as depicted in FIG. 2B. At least the p-doped gallium nitride layer 250, the quantum well region 240, and an upper portion of the n-doped gallium nitride layer 230 are etched away to form the first mesa structure 258. The method 100 at operation 130 further includes depositing a transparent conductive oxide (TCO) layer 260 on at least a portion of the p-doped gallium nitride layer 250 during a TCO deposition process, as depicted in FIG. 2C. The method 100 at operation 140 also includes forming a second mesa structure 228 from at least a second portion of the layered stack 212 during a second mesa etch process, as depicted in FIG. 2D. At least a lower portion of the n-doped gallium nitride layer 230 and the gallium nitride support layer 220 are etched away to form the second mesa structure 228. The method 100 at operation 150 also includes depositing a dielectric passivation layer 270 on the first and second mesa structures 258, 228 during a passivation layer deposition process, and at operation 160, revealing at least a portion of the TCO layer 260 in the first mesa structure 258 to form a revealed portion 262 of the TCO layer 260 and revealing at least a portion of the n-doped gallium nitride layer 230 in the second mesa structure 228 to form a revealed portion 272 of the n-doped gallium nitride layer 230, as depicted in FIG. 2E. The method 100 at operation 170 also includes depositing a p-contact layer 280 on the revealed portion of the TCO layer 260 and an n-contact layer 282 on the revealed portion of the n-doped gallium nitride layer 230, as depicted in FIG. 2F.

In one or more embodiments, the substrate 210 may be or contain one or more materials, such as sapphire, silicon, silicon carbide, silicon germanium, silicon-containing compounds, dopants thereof, or any combination thereof. The substrate may be or have any type of geometry, including rounded or squared shapes, such as a circle, a square, a rectangular, or other shapes or geometries. In some embodiments, the substrate 210 has a thickness in a range from about 50 μm to about 500 μm, such as about 50 μm to about 400 μm, about 100 μm to about 300 μm, or about 150 μm to about 200 μm.

In one or more embodiments, the gallium nitride support layer 220 may be or contain gallium nitride having high purity and none or substantially no dopants (e.g., undoped gallium nitride). In some examples, the gallium nitride support layer 220 may be or contain gallium nitride having a purity in a range from about 95 at % to about 100 at %, from about 96 at % to about 100 at %, from about 97 at % to about 100 at %, from about 98 at % to about 100 at %, from about 99 at % to about 100 at %, from about 99.5 at % to about 100 at %, from about 99.9 at % to about 100 at %, from about 99.99 at % to about 100 at %, or purer. In one or more examples, the gallium nitride support layer 220 contain gallium nitride and is completely or substantially free of a dopant. The gallium nitride support layer 220 may be deposited by one or more epitaxy processes. In one or more embodiments, the gallium nitride support layer 220 may have a thickness in a range from about 50 nm to about 5,000 nm, such as about 100 nm to about 4,500 nm, about 150 nm to about 4,000 nm, or about 200 nm to about 3,000 nm.

In one or more embodiments, the n-doped gallium nitride layer 230 may contain gallium nitride and one or more dopants selected from silicon, germanium, oxygen, sulfur, or any combination thereof. The n-doped gallium nitride layer 230 may be deposited by one or more epitaxy processes. In one or more embodiments, the n-doped gallium nitride layer 230 may have a thickness in a range from about 500 nm to about 5,000 nm, about 800 nm to about 4,500 nm, about 1,000 nm to about 4,000 nm, about 1,200 nm to about 3,000 nm, or about 1,500 nm to about 2,500 nm.

In one or more embodiments, the quantum well region 240 may contain one or multiple pairs of the alternating layers of indium gallium nitride wells 242 and gallium nitride barriers 244. In some examples, the quantum well region 240 may contain 1 pair, 2 pairs, 3 pairs, 4 pairs, 5 pairs, 6 pairs, or more of the alternating layers of indium gallium nitride wells 242 and gallium nitride barriers 244. Each of the alternating layers of indium gallium nitride wells 242 and gallium nitride barriers 244 may independently be deposited by one or more epitaxy processes. In some examples, the quantum well region 240 layer may have a thickness in a range from about 3 nm to about 50 nm, about 3 nm to about 40 nm, about 4 nm to about 30 nm, or about 5 nm to about 20 nm. In one or more examples, each of the indium gallium nitride well layers 242 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm. In some examples, each of the gallium nitride barrier layers 244 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm.

In some embodiments, the quantum well region 240 (InGaN/GaN) may be or contain multiple quantum wells (MQWs) or a single MQW of alternating nano-layers (e.g., alternating layers of indium gallium nitride wells 242 and gallium nitride barriers 244) acting as the active region in blue/green LEDs and lasers, providing high-efficiency light emission, and/or wavelength tuning. In some examples, the MQW structures, may have 3, 4, 5 or more periods, utilize GaN barriers to confine carriers within InGaN wells, with growth optimized to reduce defect density. In some examples, performance is may be improved by Si-doping the GaN barriers to prevent structural degradation. In one or more examples, the alternating thin layers (e.g., several nanometers) may be or contain indium gallium nitride (InₓGa₍₁₋ₓ₎N) and gallium nitride (GaN). The lower bandgap InGaN acts as the quantum well for carrier trapping, while the wider bandgap GaN serves as the barrier.

In one or more embodiments, the p-doped gallium nitride layer 250 may contain gallium nitride and one or more dopants selected from magnesium, beryllium, zinc, carbon, or any combination thereof. The p-doped gallium nitride layer 250 may be deposited by one or more epitaxy processes. In one or more embodiments, the p-doped gallium nitride layer 250 may have a thickness in a range from about 10 nm to about 400 nm, about 10 nm to about 350 nm, about 15 nm to about 300 nm, or about 20 nm to about 250 nm.

In one or more embodiments, the first mesa structure 258 may be produced or otherwise formed during the first mesa etch process at operation 120. The first mesa etch process may include exposing the first portion of the layered stack 212 to photolithography and at least one or more etches, such as one or more reactive ion etches, one or more dry etches, one or more wet etches, or any combination thereof. The first mesa structure 258 contains angled sides outwardly sloping from the p-doped gallium nitride layer 250 to the n-doped gallium nitride layer 230. In some examples, the first mesa structure 258 may have a lateral width in a range from about 1 μm, about 2 μm, about 3 μm, about 4 μm, or about 5 μm to about 6 μm, about 7 μm, about 8 μm, about 9 μm, or about 10 μm, for example, in a range from about 1 μm to about 10 μm, about 2 μm to about 8 μm, or about 3 μm to about 6 μm.

In one or more examples, a dry etch may employ during the first mesa etch process at operation 120 and include halogen-based etch chemistries selected to etch Group III-V semiconductor materials and/or Group III-nitride semiconductor materials, including one or more chlorine-containing compounds and/or gases, one or more bromine-based compounds and/or gases, or any combination thereof. By way of non-limiting example, the etch chemistry may be or contain one or more chlorine (Cl₂), boron trichloride (BCl₃), silicon tetrachloride (SiCl₄), hydrogen chloride (HCl), argon (Ar), gases thereof, plasmas thereof, or any combination thereof. The etch chemistry and process provides or otherwise forms the mesa with substantially vertical sidewalls. In one or more embodiments, the first mesa etch controls a sidewall profile of the mesa structure. For example, the process parameters of the plasma etching, such as ion energy, plasma density, chamber pressure, and/or gas composition, may be selected to achieve a substantially anisotropic etch, thereby defining mesa sidewalls having a controlled angle relative to a surface of the wafer. In some embodiments, the mesa sidewall angle of the first mesa structure 258 may be in a range from about 45°, about 48°, about 50°, or about 52° to about 55°, about 58°, about 60°, about 62°, about 65°, about 68°, or about 70°. The mesa sidewall angle may be advantageous for reducing electrical leakage, improving current confinement, and enhancing optical extraction or waveguide coupling efficiency in photonic interconnect applications. In one or more embodiments, the first mesa etch process may further include one or more post-etch ireatments to reduce or eliminate plasma-induced damage and contamination on mesa sidewalls. In some examples, the post-etch treatments may be or include oxygen-containing plasma treatments, hydrogen-containing plasma treatments, one or more wet cleaning processes (e.g., acid-based clean or alkaline-based clean), or combinations thereof. The post-etch treatments may remove etch residues, redeposited material, or damaged surface layers.

In one or more examples, the first mesa etch process at operation 120 may be a “die isolation” process (also known as mesa etching or device isolation) which may be used as a material-removal step to define individual LED chips and electrically separate them on a wafer. The first mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, a mesa etch process may be used to expose two different surfaces in the LED epilayer that may be coupled to corresponding electrodes or electrical contacts. For example, the mesa process may expose a p-doped GaN surface on one portion of the LED epilayer. By etching away a portion of the p-doped GaN surface (along with any intervening layers, such as an MQW region), a portion of an underlying n-doped GaN layer may be exposed to form an n-doped GaN surface. Any type of etch process may be used to expose these surfaces, including photolithography, reactive ion etches, and other etching processes.

At operation 130, the TCO layer 260 may be deposited or otherwise formed on the p-doped gallium nitride layer 250, as depicted in FIG. 2C. In some embodiments, the TCO layer 260 may be deposited in a center or inner portion of the p-doped gallium nitride layer 250, such as on an inner portion of the p-doped gallium nitride layer 250, as depicted in FIG. 2C. In other embodiments, not shown, the TCO layer 260 may be deposited across the full upper surface of the p-doped gallium nitride layer 250.

In one or more embodiments, the TCO layer 260 may be or contain indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof. In one or more examples, the TCO layer 260 may be or contain ITO. The TCO layer 260 is deposited by a sputtering process, a physical vapor deposition (PVD) process, a chemical vapor deposition (CVD) process, an atomic layer deposition (ALD) process, other deposition processes, or any combination thereof during the operation 130. In some examples, the TCO layer 260 may have a thickness in a range from about 10 nm to about 500 nm, such as about 10 nm to about 200 nm, about 10 nm to about 150 nm, or about 10 nm to about 120 nm. In one or more examples, the TCO layer 260 may have a diameter in a range from about 1 μm to about 50 μm, such as about 1 μm to about 20 μm, about 1 μm to about 10 μm, about 1 μm to about 5 μm, or about 1 μm to about 3 μm.

In one or more embodiments, the second mesa structure 228 is produced or otherwise formed during the second mesa etch process at operation 140. The second mesa etch process may include exposing the lower portion of the n-doped gallium nitride layer 230 and the gallium nitride support layer 220 to photolithography and at least one or more etches, such as one or more reactive ion etches, one or more dry etches, one or more wet etches, or any combination thereof. In some examples, the second mesa structure 228 may have a lateral width in a range from about 1 μm, about 2 μm, about 3 μm, about 5 μm, about 8 μm, about 10 μm, about 15 μm, about 20 μm, about 25 μm, about 30 μm, about 35 μm, about 40 μm, about 45 μm, about 50 μm, or about 60 μm, or greater. For example, the second mesa structure 228 may have a lateral width in a range from about 1 μm to about 50 μm, about 5 μm to about 50 μm, about 5 μm to about 40 μm, about 10 μm to about 50 μm, or about 10 μm to about 30 μm.

In one or more embodiments, the second mesa etch process at operation 140 may be utilized for etching to a depth sufficient to physically isolate neighboring micro-LED devices. The etch depth may be controlled using timed etching, endpoint detection, and/or process margin to ensure an isolation trench between adjacent dies. In some embodiments, the second mesa etch defines isolation trench sidewalls with a profile which is completely vertical or substantially vertical and maintains mechanical integrity of the micro-LED array. In some embodiments, the mesa sidewall angle of the second mesa structure 228 may be in a range from about 70°, about 72°, about 75°, or about 78° to about 80°, about 82°, about 85°, about 87°, about 88°, or about 90°. The mesa sidewall angle of the second mesa structure 228 may be advantageous for enhancing optical extraction and/or waveguide coupling efficiency in photonic interconnect applications. Following the second mesa etch process, residual etch byproducts or damaged surface regions may be removed using one or more post-etch treatments to improve electrical isolation and device reliability. In one or more examples, the mesa sidewall angle of the second mesa structure 228 may be greater than the mesa sidewall angle of the first mesa structure 258.

In one or more examples, the second mesa etch process at operation 140 may be a “die isolation” process (also known as mesa etching or device isolation) which may be used as a material-removal step to define individual LED chips and electrically separate them on a wafer. The second mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, the dielectric passivation layer 270 may be or contain one or more dielectric materials, such as aluminum oxide, silicon oxide, hafnium oxide, silicon nitride, silicon oxynitride, hafnium silicate, dopants thereof, or any combination thereof. The dielectric passivation layer 270 may be deposited at operation 150 by a CVD process, a plasma-enhanced CVD (PE-CVD) process, an ALD process, a plasma-enhanced ALD (PE-ALD) process, other deposition processes, or any combination thereof. In some examples, the dielectric passivation layer 270 may have a thickness in a range from about 5 nm to about 250 nm, about 5 nm to about 150 nm, or about 10 nm to about 100 nm.

In one or more embodiments, the method 100 further includes revealing the portion of the TCO layer 260 in the first mesa structure 258 and/or revealing the portion of the n-doped gallium nitride layer 230 in the second mesa structure 228 at operation 160. In some embodiments, the method 100 may further include one or more photolithography processes, one or more etch processes, or any combination thereof at operation 160. For example, photolithography and at least one or more etches, such as one or more reactive ion etches, one or more dry etches, one or more wet etches, or any combination thereof may be used to reveal the portion of the TCO layer 260 in the first mesa structure 258 and/or reveal the portion of the n-doped gallium nitride layer 230 in the second mesa structure 228.

In one or more embodiments, each of the p-contact layer 280 and the n-contact layer 282 may independently be or contain one or more metals, such as titanium, nickel, aluminum, rhodium, platinum, silver, gold, copper, chromium, tungsten, alloys thereof, dopants thereof, or any combination thereof. In some embodiments, each of the p-contact layer 280 and the n-contact layer 282 may independently be or contain a metal stack. Each metal stack may be or contain two, three, four, five, or more metal layers where each metal layer may be or contain a different composition relative to the other layers in the metal stack. In some examples, each metal layer may independently be or contain titanium, nickel, aluminum, rhodium, platinum, silver, gold, copper, chromium, tungsten, alloys thereof, dopants thereof, or any combination thereof. In one or more examples the metal stack may contain a first layer containing chromium, a second layer containing aluminum, a third layer containing nickel, and a fourth layer containing gold, such the fourth layer is disposed on the third layer, which is disposed on the second layer, which is disposed on the first layer (e.g., Cr/Al/Ti/Ni/Au). In other examples, the metal stack may contain a first layer containing chromium, a second layer containing platinum, and a third layer containing gold, such the third layer is disposed on the second layer, which is disposed on the first layer (e.g., Cr/Pt/Au). Each of the p-contact layer 280 and the n-contact layer 282 may be independently deposited or otherwise formed by one or more of a sputtering process, a thermal evaporation process, an electron beam (e-beam) process, an electroplating process, a PVD process, a CVD process, a PE-CVD process, an ALD process, a PE-ALD process, other deposition processes, or any combination thereof.

In one or more embodiments, the p-contact layer 280 has a circular geometry, the n-contact layer 282 may have a ring geometry, and the n-contact layer 282 is coaxial to and encompasses the p-contact layer 280. In some examples, the p-contact layer 280 may have a diameter in a range from about 1 μm to about 50 μm and a thickness in a range from about 100 nm to about 1 μm. In other embodiments, the n-contact layer 282 may have a ring geometry. In some examples, the n-contact layer 282 has a width in a range from about 1 μm to about 50 μm, a thickness in a range from about 100 nm to about 1 μm, and an outer diameter of the ring geometry in a range from about 10 μm to about 200 μm.

In one or more embodiments, as depicted in FIG. 2F, a micro-LED device 200 (e.g., processed workpiece) is provided and contains a layered stack 212 disposed on a substrate 210. The layered stack 212 contains a gallium nitride support layer 220 disposed on the substrate 210, an n-doped gallium nitride layer 230 disposed on the gallium nitride support layer 220, a quantum well region 240 disposed on the n-doped gallium nitride layer 230, the quantum well region 240 may contain alternating layers of indium gallium nitride wells 242 and gallium nitride barriers 244. A p-doped gallium nitride layer 250 may be deposited or otherwise disposed on the quantum well region 240. The micro-LED device 200 also contains a first mesa structure 258 containing at least a first portion of the layered stack 212, where at least the p-doped gallium nitride layer 250, the quantum well region 240, and an upper portion of the n-doped gallium nitride layer 230 form the first mesa structure 258. The micro-LED device 200 also contains a TCO layer 260 disposed on at least a portion of the p-doped gallium nitride layer 250, and a second mesa structure 228 containing at least a second portion of the layered stack 212. At least a lower portion of the n-doped gallium nitride layer 230 and the gallium nitride support layer 220 form the second mesa structure 228. The micro-LED device 200 also contains a dielectric passivation layer 270 disposed on a first portion of the first mesa structure 258 and a first portion of the second mesa structure 228, a revealed portion of the TCO layer 260 in the first mesa structure 258 is free or substantially free of the dielectric passivation layer 270, a revealed portion of the n-doped gallium nitride layer 230 in the second mesa structure 228 is free or substantially free of the dielectric passivation layer 270, and a p-contact layer 280 disposed on the revealed portion of the TCO layer 260 and an n-contact layer 282 disposed on the revealed portion of the n-doped gallium nitride layer 230.

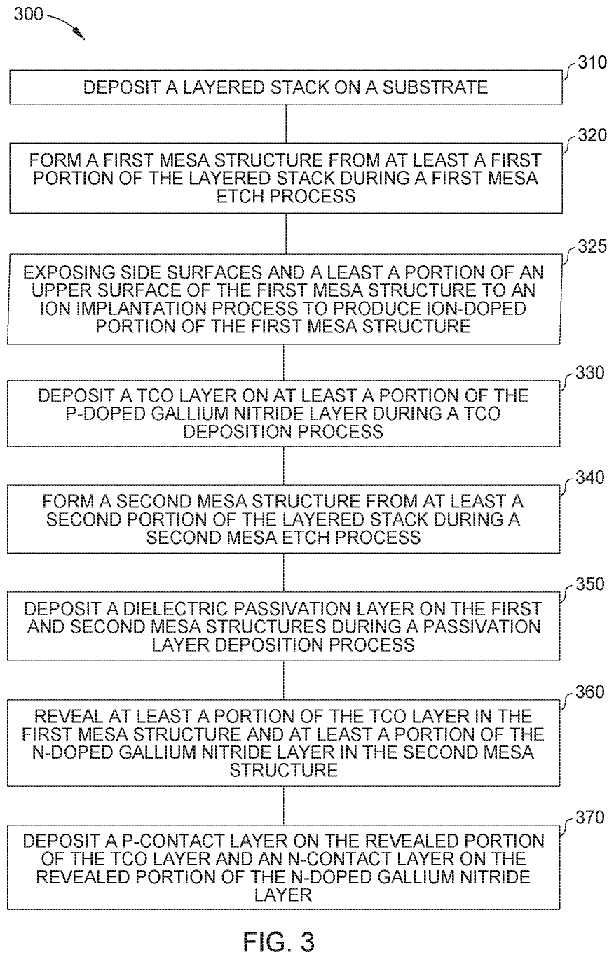

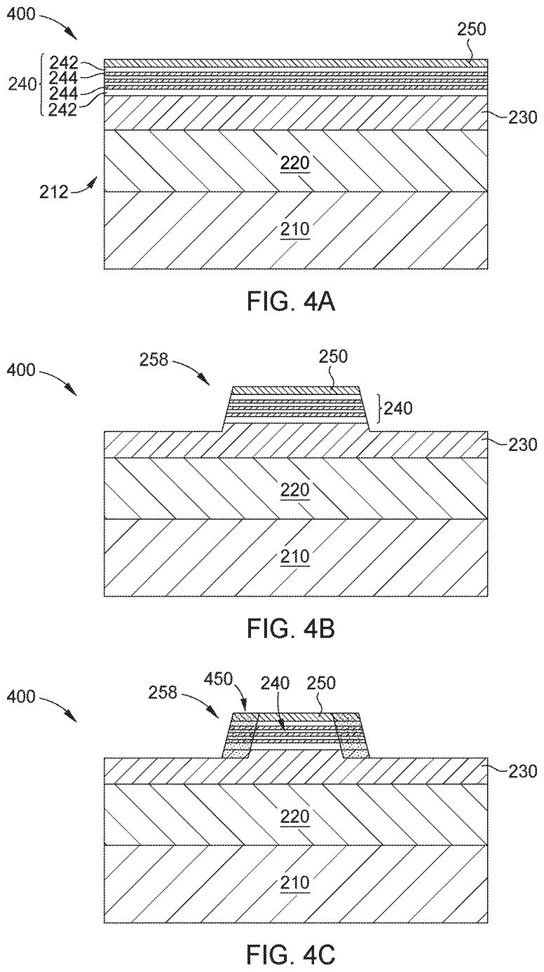

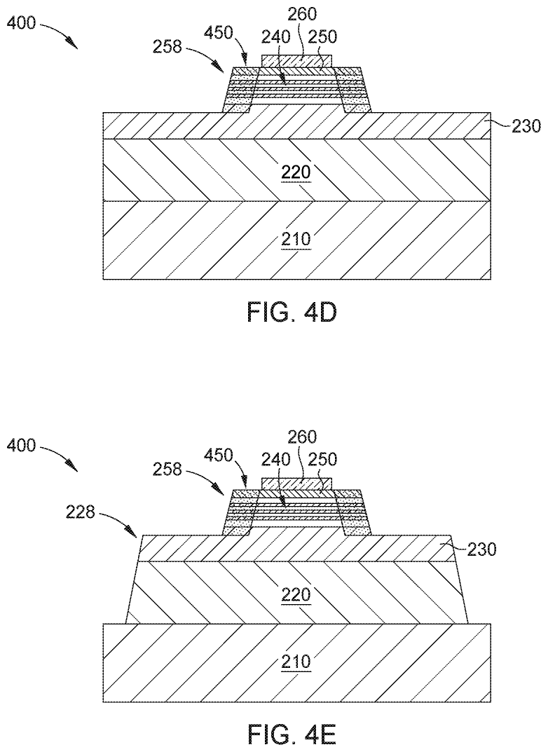

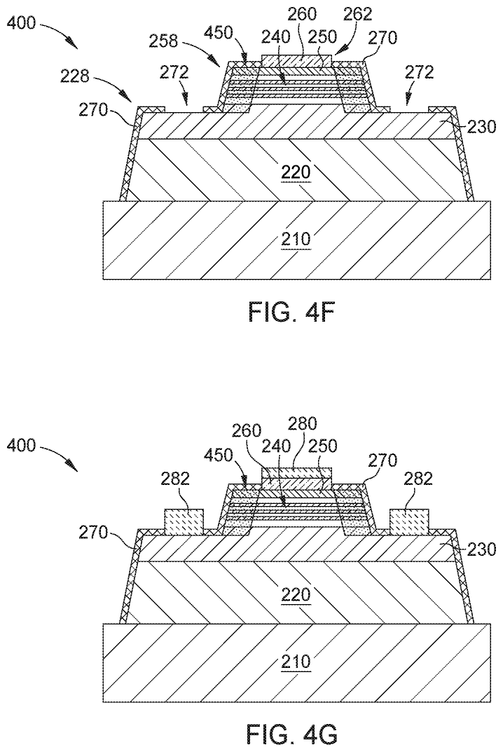

FIG. 3 is a flowchart which includes a method 300 (e.g., flow process) for producing a micro-LED device, according to one or more embodiments described and discussed herein. The method 300 includes operations 310-370, as further described and discussed below. FIGS. 4A-4G depict a cross-sectional view of a workpiece (e.g., micro-LED device) 200 at different time intervals passing through a flow process for manufacturing, forming, or otherwise producing one or more different types of micro-LED devices with coaxial contacts, the flow process may be such as the method 300 illustrated in FIG. 3, according to one or more embodiments described and discussed herein. The method 300, and variations thereof, may also be followed to produce other type of micro-LED devices, shown and not shown, in embodiments described and discussed herein.

In one or more embodiments, the method 300 for producing micro-LED devices at operation 310, illustrated in FIG. 3, is provided and includes depositing a layered stack 212 on a substrate 210, as depicted by the workpiece 400 in FIG. 4A. The layered stack 212 may contain a gallium nitride support layer 220 disposed on the substrate 210, an n-doped gallium nitride layer 230 disposed on the gallium nitride support layer 220, a quantum well region 240 disposed on the n-doped gallium nitride layer 230. A p-doped gallium nitride layer 250 may be deposited or otherwise disposed on the quantum well region 240. The quantum well region 240 contains alternating layers of indium gallium nitride wells 242 and gallium nitride barriers 244. The method 300 at operation 320 also includes forming a first mesa structure 258 from at least a first portion of the layered stack 212 during a first mesa etch process, as depicted in FIG. 4B. At least the p-doped gallium nitride layer 250, the quantum well region 240, and an upper portion of the n-doped gallium nitride layer 230 are etched away to form the first mesa structure 258. The method 300 at operation 325 also includes exposing side surfaces and at least a portion of an upper surface of the first mesa structure 258 to an ion implantation process to produce ion-doped portion 450 of the first mesa structure 258, as depicted in FIG. 4C. The method 300 at operation 330 further includes depositing a TCO layer 260 on at least a portion of the p-doped gallium nitride layer 250 during a TCO deposition process, as depicted in FIG. 4D. The method 300 at operation 340 also includes forming a second mesa structure 228 from at least a second portion of the layered stack 212 during a second mesa etch process, as depicted in FIG. 4E. At least a lower portion of the n-doped gallium nitride layer 230 and the gallium nitride support layer 220 are etched away to form the second mesa structure 228. The method 300 at operation 350 also includes depositing a dielectric passivation layer 270 on the first and second mesa structures 258, 228 during a passivation layer deposition process, and at operation 360, revealing at least a portion of the TCO layer 260 in the first mesa structure 258 to form a revealed portion 262 of the TCO layer 260 and revealing at least a portion of the n-doped gallium nitride layer 230 in the second mesa structure 228 to form a revealed portion 272 of the n-doped gallium nitride layer 230, as depicted in FIG. 4F. The method 300 at operation 370 also includes depositing a p-contact layer 280 on the revealed portion of the TCO layer 260 and an n-contact layer 282 on the revealed portion of the n-doped gallium nitride layer 230, as depicted in FIG. 4G, as the micro-LED device (e.g., processed workpiece) 400.

In one or more embodiments, the substrate 210 may be or contain one or more materials, such as sapphire, silicon, silicon carbide, silicon germanium, silicon-containing compounds, dopants thereof, or any combination thereof. The substrate may be or have any type of geometry, including rounded or squared shapes, such as a circle, a square, a rectangular, or other shapes or geometries. In some embodiments, the substrate 210 has a thickness in a range from about 50 μm to about 500 μm, such as about 50 μm to about 400 μm, about 100 μm to about 300 μm, or about 150 μm to about 200 μm.

In one or more embodiments, the gallium nitride support layer 220 may be or contain gallium nitride having high purity and none or substantially no dopants (e.g., undoped gallium nitride). In some examples, the gallium nitride support layer 220 may be or contain gallium nitride having a purity in a range from about 95 at % to about 100 at %, from about 96 at % to about 100 at %, from about 97 at % to about 100 at %, from about 98 at % to about 100 at %, from about 99 at % to about 100 at %, from about 99.5 at % to about 100 at %, from about 99.9 at % to about 100 at %, from about 99.99 at % to about 100 at %, or purer. In one or more examples, the gallium nitride support layer 220 contain gallium nitride and is completely or substantially free of a dopant. The gallium nitride support layer 220 may be deposited by one or more epitaxy processes. In one or more embodiments, the gallium nitride support layer 220 may have a thickness in a range from about 50 nm to about 5,000 nm, such as about 100 nm to about 4,500 nm, about 150 nm to about 4,000 nm, or about 200 nm to about 3,000 nm.

In one or more embodiments, the n-doped gallium nitride layer 230 may contain gallium nitride and one or more dopants selected from silicon, germanium, oxygen, sulfur, or any combination thereof. The n-doped gallium nitride layer 230 may be deposited by one or more epitaxy processes. In one or more embodiments, the n-doped gallium nitride layer 230 may have a thickness in a range from about 500 nm to about 5,000 nm, about 800 nm to about 4,500 nm, about 1,000 nm to about 4,000 nm, about 1,200 nm to about 3,000 nm, or about 1,500 nm to about 2,500 nm.

In one or more embodiments, the quantum well region 240 may contain one or multiple pairs of the alternating layers of indium gallium nitride wells 242 and gallium nitride barriers 244. In some examples, the quantum well region 240 may contain 1 pair, 2 pairs, 3 pairs, 4 pairs, 5 pairs, 6 pairs, or more of the alternating layers of indium gallium nitride wells 242 and gallium nitride barriers 244. Each of the alternating layers of indium gallium nitride wells 242 and gallium nitride barriers 244 may independently be deposited by one or more epitaxy processes. In some examples, the quantum well region 240 layer may have a thickness in a range from about 3 nm to about 50 nm, about 3 nm to about 40 nm, about 4 nm to about 30 nm, or about 5 nm to about 20 nm. In one or more examples, each of the indium gallium nitride well layers 242 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm. In some examples, each of the gallium nitride barrier layers 244 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm.

In some embodiments, the quantum well region 240 (InGaN/GaN) may be or contain multiple quantum wells (MQWs) or a single MQW of alternating nano-layers (e.g., alternating layers of indium gallium nitride wells 242 and gallium nitride barriers 244) acting as the active region in blue/green LEDs and lasers, providing high-efficiency light emission, and/or wavelength tuning. In some examples, the MQW structures, may have 3, 4, 5 or more periods, utilize GaN barriers to confine carriers within InGaN wells, with growth optimized to reduce defect density. In some examples, performance is may be improved by Si-doping the GaN barriers to prevent structural degradation. In one or more examples, the alternating thin layers (e.g., several nanometers) may be or contain indium gallium nitride (InₓGa₍₁₋ₓ₎N) and gallium nitride (GaN). The lower bandgap InGaN acts as the quantum well for carrier trapping, while the wider bandgap GaN serves as the barrier.

In one or more embodiments, the p-doped gallium nitride layer 250 may contain gallium nitride and one or more dopants selected from magnesium, beryllium, zinc, carbon, or any combination thereof. The p-doped gallium nitride layer 250 may be deposited by one or more epitaxy processes. In one or more embodiments, the p-doped gallium nitride layer 250 may have a thickness in a range from about 10 nm to about 400 nm, about 10 nm to about 350 nm, about 15 nm to about 300 nm, or about 20 nm to about 250 nm.

In one or more embodiments, the first mesa structure 258 may be produced or otherwise formed during the first mesa etch process at operation 320. The first mesa etch process may include exposing the first portion of the layered stack 212 to photolithography and at least one or more etches, such as one or more reactive ion etches, one or more dry etches, one or more wet etches, or any combination thereof. The first mesa structure 258 contains angled sides outwardly sloping from the p-doped gallium nitride layer 250 to the n-doped gallium nitride layer 230. In some examples, the first mesa structure 258 may have a lateral width in a range from about 1 μm, about 2 μm, about 3 μm, about 4 μm, or about 5 μm to about 6 μm, about 7 μm, about 8 μm, about 9 μm, or about 10 μm, for example, in a range from about 1 μm to about 10 μm, about 2 μm to about 8 μm, or about 3 μm to about 6 μm.

In one or more examples, a dry etch may employ during the first mesa etch process at operation 320 and include halogen-based etch chemistries selected to etch Group III-V semiconductor materials and/or Group III-nitride semiconductor materials, including one or more chlorine-containing compounds and/or gases, one or more bromine-based compounds and/or gases, or any combination thereof. By way of non-limiting example, the etch chemistry may be or contain one or more chlorine (Cl₂), boron trichloride (BCl₃), silicon tetrachloride (SiCl₄), hydrogen chloride (HCl), argon (Ar), gases thereof, plasmas thereof, or any combination thereof. The etch chemistry and process provides or otherwise forms the mesa with substantially vertical sidewalls. In one or more embodiments, the first mesa etch controls a sidewall profile of the mesa structure. For example, the process parameters of the plasma etching, such as ion energy, plasma density, chamber pressure, and/or gas composition, may be selected to achieve a substantially anisotropic etch, thereby defining mesa sidewalls having a controlled angle relative to a surface of the wafer. In some embodiments, the mesa sidewall angle of the first mesa structure 258 may be in a range from about 45°, about 48°, about 50°, or about 52° to about 55°, about 58°, about 60°, about 62°, about 65°, about 68°, or about 70°. The mesa sidewall angle may be advantageous for reducing electrical leakage, improving current confinement, and enhancing optical extraction or waveguide coupling efficiency in photonic interconnect applications. In one or more embodiments, the first mesa etch process may further include one or more post-etch treatments to reduce or eliminate plasma-induced damage and contamination on mesa sidewalls. In some examples, the post-etch treatments may be or include oxygen-containing plasma treatments, hydrogen-containing plasma treatments, one or more wet cleaning processes (e.g., acid-based clean or alkaline-based clean), or combinations thereof. The post-etch treatments may remove etch residues, redeposited material, or damaged surface layers.

In one or more examples, the first mesa etch process at operation 320 may be a “die isolation” process (also known as mesa etching or device isolation) which may be used as a material-removal step to define individual LED chips and electrically separate them on a wafer. The first mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, a mesa etch process may be used to expose two different surfaces in the LED epilayer that may be coupled to corresponding electrodes or electrical contacts. For example, the mesa process may expose a p-doped GaN surface on one portion of the LED epilayer. By etching away a portion of the p-doped GaN surface (along with any intervening layers, such as an MQW region), a portion of an underlying n-doped GaN layer may be exposed to form an n-doped GaN surface. Any type of etch process may be used to expose these surfaces, including photolithography, reactive ion etches, and other etching processes.

In one or more embodiments, the ion-doped portion 450 of the first mesa structure 258 may be fabricated, produced, or otherwise formed during one or more ion implantation processes operation 325 of the method 300. The outer side surfaces and at least a portion of a portion of the upper surface of the first mesa structure 258 may be exposed to the ion implantation process while producing the ion-doped portion 450 of the first mesa structure 258, as depicted in FIG. 4C.

In some embodiments, the ion implantation process may include exposing the side surfaces and the portion of the upper surface of the first mesa structure 258 to one or more elemental ions via an ion implanter system. The one or more elemental ions may be or contain ions of hydrogen, helium, boron, carbon, nitrogen, oxygen, fluorine, silicon, phosphorus, argon, chromium, iron, zinc, titanium, or any combination thereof. In one or more examples, the ion implanter system may generate an implantation energy in a range from about 10 keV to about 100 keV. In some examples, the one or more elemental ions penetrate into the side surfaces and the portion of the upper surface of the first mesa structure 258 to a depth in a range from about 200 nm to about 10 μm.

At operation 330, the TCO layer 260 may be deposited or otherwise formed on the p-doped gallium nitride layer 250, as depicted in FIG. 4D. In some examples, the TCO layer 260 may be deposited in the center of the p-doped gallium nitride layer 250, such as on an inner portion of the p-doped gallium nitride layer 250 which is free of or substantially free of doped ions, such as the ion-doped portion 450. As such, an outer portion of the p-doped gallium nitride layer 250 containing the ion-doped portion 450 may remain completely free or substantially free of the TCO layer 260.

In one or more embodiments, the TCO layer 260 may be or contain indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof. In one or more examples, the TCO layer 260 may be or contain ITO. The TCO layer 260 is deposited by a sputtering process, a PVD process, a CVD process, an ALD process, other deposition processes, or any combination thereof during the operation 330. In some examples, the TCO layer 260 may have a thickness in a range from about 10 nm to about 500 nm, such as about 10 nm to about 200 nm, about 10 nm to about 150 nm, or about 10 nm to about 120 nm. In one or more examples, the TCO layer 260 may have a diameter in a range from about 1 μm to about 50 μm, such as about 1 μm to about 20 μm, about 1 μm to about 10 μm, about 1 μm to about 5 μm, or about 1 μm to about 3 μm.

In one or more embodiments, the second mesa structure 228 is produced or otherwise formed during the second mesa etch process at operation 340. The second mesa etch process may include exposing the lower portion of the n-doped gallium nitride layer 230 and the gallium nitride support layer 220 to photolithography and at least one or more etches, such as one or more reactive ion etches, one or more dry etches, one or more wet etches, or any combination thereof. In some examples, the second mesa structure 228 may have a lateral width in a range from about 1 μm, about 2 μm, about 3 μm, about 5 μm, about 8 μm, about 10 μm, about 15 μm, about 20 μm, about 25 μm, about 30 μm, about 35 μm, about 40 μm, about 45 μm, about 50 μm, or about 60 μm, or greater. For example, the second mesa structure 228 may have a lateral width in a range from about 1 μm to about 50 μm, about 5 μm to about 50 μm, about 5 μm to about 40 μm, about 10 μm to about 50 μm, or about 10 μm to about 30 μm.

In one or more embodiments, the second mesa etch process at operation 340 may be utilized for etching to a depth sufficient to physically isolate neighboring micro-LED devices. The etch depth may be controlled using timed etching, endpoint detection, and/or process margin to ensure an isolation trench between adjacent dies. In some embodiments, the second mesa etch defines isolation trench sidewalls with a profile which is completely vertical or substantially vertical and maintains mechanical integrity of the micro-LED array. In some embodiments, the mesa sidewall angle of the second mesa structure 228 may be in a range from about 70°, about 72°, about 75°, or about 78° to about 80°, about 82°, about 85°, about 87°, about 88°, or about 90°. The mesa sidewall angle of the second mesa structure 228 may be advantageous for enhancing optical extraction and/or waveguide coupling efficiency in photonic interconnect applications. Following the second mesa etch process, residual etch byproducts or damaged surface regions may be removed using one or more post-etch treatments to improve electrical isolation and device reliability. In one or more examples, the mesa sidewall angle of the second mesa structure 228 may be greater than the mesa sidewall angle of the first mesa structure 258.

In one or more examples, the second mesa etch process at operation 340 may be a “die isolation” process (also known as mesa etching or device isolation) which may be used as a material-removal step to define individual LED chips and electrically separate them on a wafer. The second mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, the dielectric passivation layer 270 may be or contain one or more dielectric materials, such as aluminum oxide, silicon oxide, hafnium oxide, silicon nitride, silicon oxynitride, hafnium silicate, dopants thereof, or any combination thereof. The dielectric passivation layer 270 may be deposited at operation 350 by a CVD process, a PE-CVD process, an ALD process, a PE-ALD process, other deposition processes, or any combination thereof. In some examples, the dielectric passivation layer 270 may have a thickness in a range from about 5 nm to about 250 nm, about 5 nm to about 150 nm, or about 10 nm to about 100 nm.

In one or more embodiments, the method 300 further includes revealing the portion of the TCO layer 260 in the first mesa structure 258 and/or revealing the portion of the n-doped gallium nitride layer 230 in the second mesa structure 228 at operation 360. In some embodiments, the method 300 may further include one or more photolithography processes, one or more etch processes, or any combination thereof at operation 360. For example, photolithography and at least one or more etches, such as one or more reactive ion etches, one or more dry etches, one or more wet etches, or any combination thereof may be used to reveal the portion of the TCO layer 260 in the first mesa structure 258 and/or reveal the portion of the n-doped gallium nitride layer 230 in the second mesa structure 228.

In one or more embodiments, each of the p-contact layer 280 and the n-contact layer 282 may independently be or contain one or more metals, such as titanium, nickel, aluminum, rhodium, platinum, silver, gold, copper, chromium, tungsten, alloys thereof, dopants thereof, or any combination thereof. In some embodiments, each of the p-contact layer 280 and the n-contact layer 282 may independently be or contain a metal stack. Each metal stack may be or contain two, three, four, five, or more metal layers where each metal layer may be or contain a different composition relative to the other layers in the metal stack. In some examples, each metal layer may independently be or contain titanium, nickel, aluminum, rhodium, platinum, silver, gold, copper, chromium, tungsten, alloys thereof, dopants thereof, or any combination thereof. In one or more examples the metal stack may contain a first layer containing chromium, a second layer containing aluminum, a third layer containing nickel, and a fourth layer containing gold, such the fourth layer is disposed on the third layer, which is disposed on the second layer, which is disposed on the first layer (e.g., Cr/Al/Ti/Ni/Au). In other examples, the metal stack may contain a first layer containing chromium, a second layer containing platinum, and a third layer containing gold, such the third layer is disposed on the second layer, which is disposed on the first layer (e.g., Cr/Pt/Au). Each of the p-contact layer 280 and the n-contact layer 282 may be independently deposited or otherwise formed by one or more of a sputtering process, a thermal evaporation process, an electron beam (e-beam) process, an electroplating process, a PVD process, a CVD process, a PE-CVD process, an ALD process, a PE-ALD process, other deposition processes, or any combination thereof.

In one or more embodiments, the p-contact layer 280 has a circular geometry, the n-contact layer 282 may have a ring geometry, and the n-contact layer 282 is coaxial to and encompasses the p-contact layer 280. In some examples, the p-contact layer 280 may have a diameter in a range from about 1 μm to about 50 μm and a thickness in a range from about 100 nm to about 1 μm. In other embodiments, the n-contact layer 282 may have a ring geometry. In some examples, the n-contact layer 282 has a width in a range from about 1 μm to about 50 μm, a thickness in a range from about 100 nm to about 1 μm, and an outer diameter of the ring geometry in a range from about 10 μm to about 200 μm.

In one or more embodiments, as depicted in FIG. 4G, a micro-LED device 400 (e.g., processed workpiece) is provided and contains a layered stack 212 disposed on a substrate 210. The layered stack 212 contains a gallium nitride support layer 220 disposed on the substrate 210, an n-doped gallium nitride layer 230 disposed on the gallium nitride support layer 220, a quantum well region 240 disposed on the n-doped gallium nitride layer 230, the quantum well region 240 may contain alternating layers of indium gallium nitride wells 242 and gallium nitride barriers 244. A p-doped gallium nitride layer 250 may be deposited or otherwise disposed on the quantum well region 240. The micro-LED device 400 also contains a first mesa structure 258 containing at least a first portion of the layered stack 212, where at least the p-doped gallium nitride layer 250, the quantum well region 240, and an upper portion of the n-doped gallium nitride layer 230 form the first mesa structure 258. The micro-LED device 400 also contains a TCO layer 260 disposed on at least a portion of the p-doped gallium nitride layer 250, and a second mesa structure 228 containing at least a second portion of the layered stack 212. At least a lower portion of the n-doped gallium nitride layer 230 and the gallium nitride support layer 220 form the second mesa structure 228. The micro-LED device 400 also contains a dielectric passivation layer 270 disposed on a first portion of the first mesa structure 258 and a first portion of the second mesa structure 228, a revealed portion of the TCO layer 260 in the first mesa structure 258 is free or substantially free of the dielectric passivation layer 270, a revealed portion of the n-doped gallium nitride layer 230 in the second mesa structure 228 is free or substantially free of the dielectric passivation layer 270, and a p-contact layer 280 disposed on the revealed portion of the TCO layer 260 and an n-contact layer 282 disposed on the revealed portion of the n-doped gallium nitride layer 230.

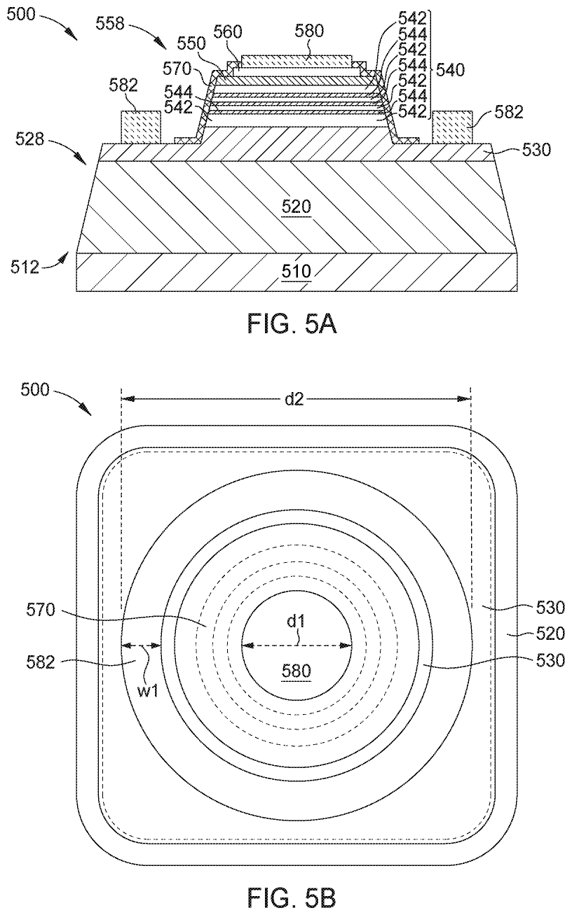

In one or more embodiments, coaxial geometry provides signal shielding, minimizes signal loss, minimizes interference between adjacent dies, ensures controllable and predictable impedance, uniforms electrical signal injection and uniforms light emission distribution, as depicted in FIGS. 5A-8B. Coaxial contact geometry provides signal shielding, minimizes signal loss, minimizes interference between adjacent dies, ensures controllable and predictable impedance, ensures uniform electrical signal injection and uniform light emission distribution. A small p-contact provides current conferment at center of mesa, increases current density for a certain current injected into a micro-LED. In some embodiments, the metal contacts cover mesa and die sidewalls, such that light extraction efficiency can be significantly improved over traditional LEDs, and ensuring high light output power and hence high signal to noise rate for data communication over traditional LEDs.

FIGS. 5A and 5B depict a cross-sectional view and a top view, respectively, of a micro-LED device 500 with coaxial contacts, according to one or more embodiments described and discussed herein. For example, FIGS. 5A-5B depict a coaxial configuration for the p- and n-contacts of each micro-LED device 500, which is different from conventional micro-LEDs with contacts side by side, according to one or more embodiments described and discussed herein.

In one or more embodiments, as depicted in FIGS. 5A-5B, a micro-LED device 500 (e.g., processed workpiece) is provided and contains a layered stack 512 disposed on a substrate 510. The substrate 510 and the layered stack 512 may be the same substrate and contain the same layers and/or materials as described and discussed above in generally, as well as for the substrate 210 and the layered stack 212. The layered stack 512 contains a gallium nitride support layer 520 disposed on the substrate 510, an n-doped gallium nitride layer 530 disposed on the gallium nitride support layer 520, a quantum well region 540 disposed on the n-doped gallium nitride layer 530, the quantum well region 540 may contain alternating layers of indium gallium nitride wells 542 and gallium nitride barriers 544.

A p-doped gallium nitride layer 550 may be deposited or otherwise disposed on the quantum well region 540. The micro-LED device 500 also contains a first mesa structure 558 containing at least a first portion of the layered stack 512, where at least the p-doped gallium nitride layer 550, the quantum well region 540, and an upper portion of the n-doped gallium nitride layer 530 form the first mesa structure 558. The micro-LED device 500 also contains a TCO layer 560 disposed on at least a portion of the p-doped gallium nitride layer 550, and a second mesa structure 528 containing at least a second portion of the layered stack 512. At least a lower portion of the n-doped gallium nitride layer 530 and the gallium nitride support layer 520 form the second mesa structure 528. The micro-LED device 500 also contains a dielectric passivation layer 570 disposed on a first portion of the first mesa structure 558 and a first portion of the second mesa structure 528, a revealed portion of the TCO layer 560 in the first mesa structure 558 is free or substantially free of the dielectric passivation layer 570, a revealed portion of the n-doped gallium nitride layer 530 in the second mesa structure 528 is free or substantially free of the dielectric passivation layer 570, and a p-contact layer 580 disposed on the revealed portion of the TCO layer 560 and an n-contact layer 582 disposed on the revealed portion of the n-doped gallium nitride layer 530.

In the embodiments described and discussed herein, the n-doped gallium nitride layer 530, the quantum well region 540, the p-doped gallium nitride layer 550, the TCO layer 560, the dielectric passivation layer 570, the p-contact layer 580, and the n-contact layer 582 may be or contain the same layers and/or materials as described and discussed above, as well as fabricated, produced, or otherwise formed by the same methods and process as described and discussed above in generally, as well as for the n-doped gallium nitride layer 230, the quantum well region 240, the p-doped gallium nitride layer 250, the TCO layer 260, the dielectric passivation layer 270, the p-contact layer 280, and the n-contact layer 282, respectively. Also, the first mesa structure 558 and the second mesa structure 528 may be fabricated, produced, or otherwise formed by the same methods and process as described and discussed above in generally, as well as for forming the first mesa structure 258 and the second mesa structure 228.

In some embodiments, the micro-LED device 500 may contain the p-contact layer 580 and the n-contact layer 582 which are coaxial with each other. In some examples, the p-contact layer 580 has a circular geometry, the n-contact layer 582 has a ring geometry, and the n-contact layer 582 encompasses the p-contact 580. In one or more embodiments, the p-contact layer 580 has a diameter d1, and the n-contact layer 582 has an outer diameter d2 and a width of w1, measured as illustrated in FIG. 5B. In one or more examples, the diameter d1 of the p-contact layer 580 may be in a range from about 4 μm to about 10 μm, such as about 5 μm to about 9 μm, or about 6 μm to about 8 μm. In one or more examples, the outer diameter d2 of the n-contact layer 582 may be in a range from about 20 μm to about 50 μm, such as about 25 μm to about 50 μm, about 30 μm to about 50 μm, about 40 μm to about 50 μm, or about 40 μm to about 45 μm. In one or more examples, the width of w1 of the n-contact layer 582 may be in a range from about 2 μm to about 20 μm, such as about 3 μm to about 18 μm, about 4 μm to about 15 μm, or about 5 μm to about 10 μm.

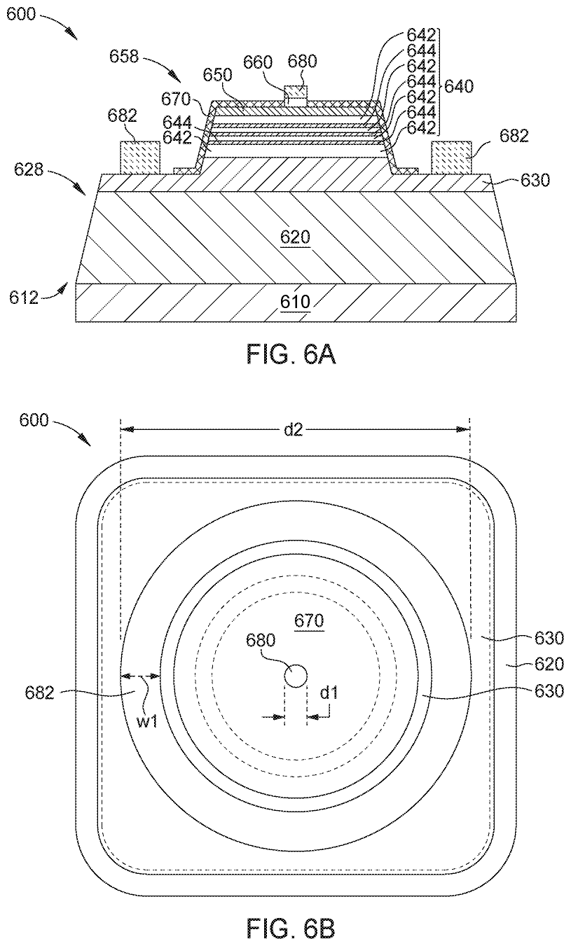

FIGS. 6A and 6B depict a cross-sectional view and a top view, respectively, of a micro-LED device 600 with coaxial contacts, according to one or more embodiments described and discussed herein. For example, FIGS. 6A-6B depict the micro-LED device 600 containing a p-contact which may be much smaller than the mesa, so current is confined at center of mesa, ensuring a high current density for high modulation bandwidth, according to one or more embodiments described and discussed herein.

In one or more embodiments, as depicted in FIGS. 6A-6B, a micro-LED device 600 (e.g., processed workpiece) is provided and contains a layered stack 612 disposed on a substrate 610. The substrate 610 and the layered stack 612 may be the same substrate and contain the same layers and/or materials as described and discussed above in generally, as well as for the substrate 210 and the layered stack 212. The layered stack 612 contains a gallium nitride support layer 620 disposed on the substrate 610, an n-doped gallium nitride layer 630 disposed on the gallium nitride support layer 620, a quantum well region 640 disposed on the n-doped gallium nitride layer 630, the quantum well region 640 may contain alternating layers of indium gallium nitride wells 642 and gallium nitride barriers 644.

A p-doped gallium nitride layer 650 may be deposited or otherwise disposed on the quantum well region 640. The micro-LED device 600 also contains a first mesa structure 658 containing at least a first portion of the layered stack 612, where at least the p-doped gallium nitride layer 650, the quantum well region 640, and an upper portion of the n-doped gallium nitride layer 630 form the first mesa structure 658. The micro-LED device 600 also contains a TCO layer 660 disposed on at least a portion of the p-doped gallium nitride layer 650, and a second mesa structure 628 containing at least a second portion of the layered stack 612. At least a lower portion of the n-doped gallium nitride layer 630 and the gallium nitride support layer 620 form the second mesa structure 628. The micro-LED device 600 also contains a dielectric passivation layer 670 disposed on a first portion of the first mesa structure 658 and a first portion of the second mesa structure 628, a revealed portion of the TCO layer 660 in the first mesa structure 658 is free or substantially free of the dielectric passivation layer 670, a revealed portion of the n-doped gallium nitride layer 630 in the second mesa structure 628 is free or substantially free of the dielectric passivation layer 670, and a p-contact layer 680 disposed on the revealed portion of the TCO layer 660 and an n-contact layer 682 disposed on the revealed portion of the n-doped gallium nitride layer 630.

In the embodiments described and discussed herein, the n-doped gallium nitride layer 630, the quantum well region 640, the p-doped gallium nitride layer 650, the TCO layer 660, the dielectric passivation layer 670, the p-contact layer 680, and the n-contact layer 682 may be or contain the same layers and/or materials as described and discussed above, as well as fabricated, produced, or otherwise formed by the same methods and process as described and discussed above in generally, as well as for the n-doped gallium nitride layer 230, the quantum well region 240, the p-doped gallium nitride layer 250, the TCO layer 260, the dielectric passivation layer 270, the p-contact layer 280, and the n-contact layer 282, respectively. Also, the first mesa structure 658 and the second mesa structure 628 may be fabricated, produced, or otherwise formed by the same methods and process as described and discussed above in generally, as well as for forming the first mesa structure 258 and the second mesa structure 228.

In some embodiments, the micro-LED device 600 may contain the p-contact layer 680 and the n-contact layer 682 which are coaxial with each other. In some examples, the p-contact layer 680 has a circular geometry, the n-contact layer 682 has a ring geometry, and the n-contact layer 682 encompasses the p-contact 680. In one or more embodiments, the p-contact layer 680 has a diameter d1, and the n-contact layer 682 has an outer diameter d2 and a width of w1, measured as illustrated in FIG. 6B. In one or more examples, the diameter d1 of the p-contact layer 680 may be in a range from about 0.5 μm to about 4 μm, such as about 0.5 μm to about 3 μm, or about 1 μm to about 3 μm, about 1 μm to about 2 μm. In one or more examples, the outer diameter d2 of the n-contact layer 682 may be in a range from about 20 μm to about 50 μm, such as about 25 μm to about 50 μm, about 30 μm to about 50 μm, about 40 μm to about 50μm, or about 40 μm to about 45 μm. In one or more examples, the width of w1 of the n-contact layer 682 may be in a range from about 2 μm to about 20 μm, such as about 3 μm to about 18 μm, about 4 μm to about 15 μm, or about 5 μm to about 10 μm.

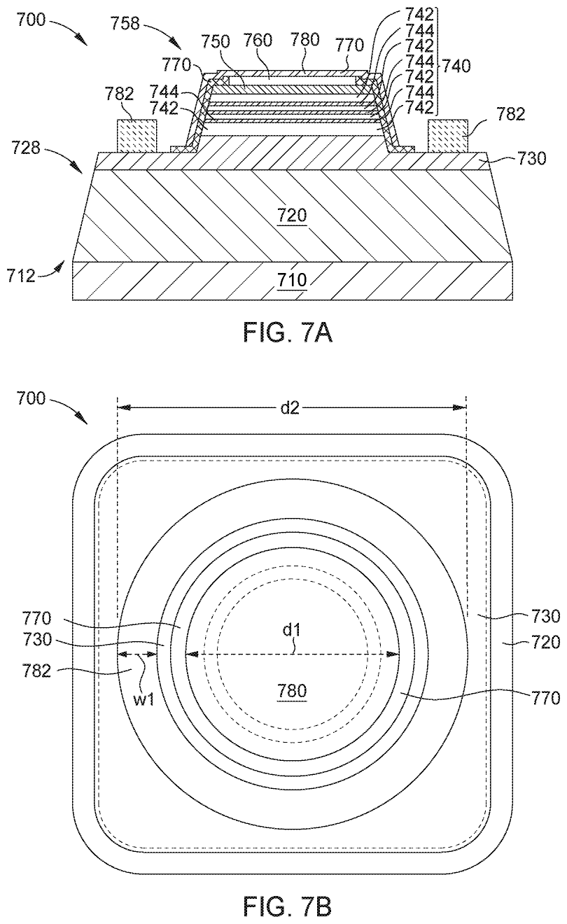

FIGS. 7A and 7B depict a cross-sectional view and a top view, respectively, of a micro-LED device 700 with coaxial contacts, according to one or more embodiments described and discussed herein. For example, FIGS. 7A-7B depict the micro-LED device 700 containing a p-contact which may cover the whole mesa including the mesa sidewall, and act as a mirror, so light extraction efficiency can be improved, according to one or more embodiments described and discussed herein.

In one or more embodiments, as depicted in FIGS. 7A-7B, a micro-LED device 700 (e.g., processed workpiece) is provided and contains a layered stack 712 disposed on a substrate 710. The substrate 710 and the layered stack 712 may be the same substrate and contain the same layers and/or materials as described and discussed above in generally, as well as for the substrate 210 and the layered stack 212. The layered stack 712 contains a gallium nitride support layer 720 disposed on the substrate 710, an n-doped gallium nitride layer 730 disposed on the gallium nitride support layer 720, a quantum well region 740 disposed on the n-doped gallium nitride layer 730, the quantum well region 740 may contain alternating layers of indium gallium nitride wells 742 and gallium nitride barriers 744.

A p-doped gallium nitride layer 750 may be deposited or otherwise disposed on the quantum well region 740. The micro-LED device 700 also contains a first mesa structure 758 containing at least a first portion of the layered stack 712, where at least the p-doped gallium nitride layer 750, the quantum well region 740, and an upper portion of the n-doped gallium nitride layer 730 form the first mesa structure 758. The micro-LED device 700 also contains a TCO layer 760 disposed on at least a portion of the p-doped gallium nitride layer 750, and a second mesa structure 728 containing at least a second portion of the layered stack 712. At least a lower portion of the n-doped gallium nitride layer 730 and the gallium nitride support layer 720 form the second mesa structure 728. The micro-LED device 700 also contains a dielectric passivation layer 770 disposed on a first portion of the first mesa structure 758 and a first portion of the second mesa structure 728, a revealed portion of the TCO layer 760 in the first mesa structure 758 is free or substantially free of the dielectric passivation layer 770, a revealed portion of the n-doped gallium nitride layer 730 in the second mesa structure 728 is free or substantially free of the dielectric passivation layer 770, and a p-contact layer 780 disposed on the revealed portion of the TCO layer 760 and an n-contact layer 782 disposed on the revealed portion of the n-doped gallium nitride layer 730.

In the embodiments described and discussed herein, the n-doped gallium nitride layer 730, the quantum well region 740, the p-doped gallium nitride layer 750, the TCO layer 760, the dielectric passivation layer 770, the p-contact layer 780, and the n-contact layer 782 may be or contain the same layers and/or materials as described and discussed above, as well as fabricated, produced, or otherwise formed by the same methods and process as described and discussed above in generally, as well as for the n-doped gallium nitride layer 230, the quantum well region 240, the p-doped gallium nitride layer 250, the TCO layer 260, the dielectric passivation layer 270, the p-contact layer 280, and the n-contact layer 282, respectively. Also, the first mesa structure 758 and the second mesa structure 728 may be fabricated, produced, or otherwise formed by the same methods and process as described and discussed above in generally, as well as for forming the first mesa structure 258 and the second mesa structure 228.

In some embodiments, the micro-LED device 700 may contain the p-contact layer 780 and the n-contact layer 782 which are coaxial with each other. In some examples, the p-contact layer 780 has a circular geometry, the n-contact layer 782 has a ring geometry, and the n-contact layer 782 encompasses the p-contact 780. In one or more embodiments, the p-contact layer 780 has a diameter d1, and the n-contact layer 782 has an outer diameter d2 and a width of w1, measured as illustrated in FIG. 7B. In one or more examples, the diameter d1 of the p-contact layer 780 may be in a range from about 5 μm to about 30 μm, such as about 8 μm to about 28 μm, or about 10 μm to about 25 μm, about 15 μm to about 20 μm. In one or more examples, the outer diameter d2 of the n-contact layer 782 may be in a range from about 20 μm to about 50 μm, such as about 25 μm to about 50 μm, about 30 μm to about 50 μm, about 40 μm to about 50 μm, or about 40 μm to about 45 μm. In one or more examples, the width of w1 of the n-contact layer 782 may be in a range from about 2 μm to about 20 μm, such as about 3 μm to about 18 μm, about 4 μm to about 15 μm, or about 5 μm to about 10 μm.

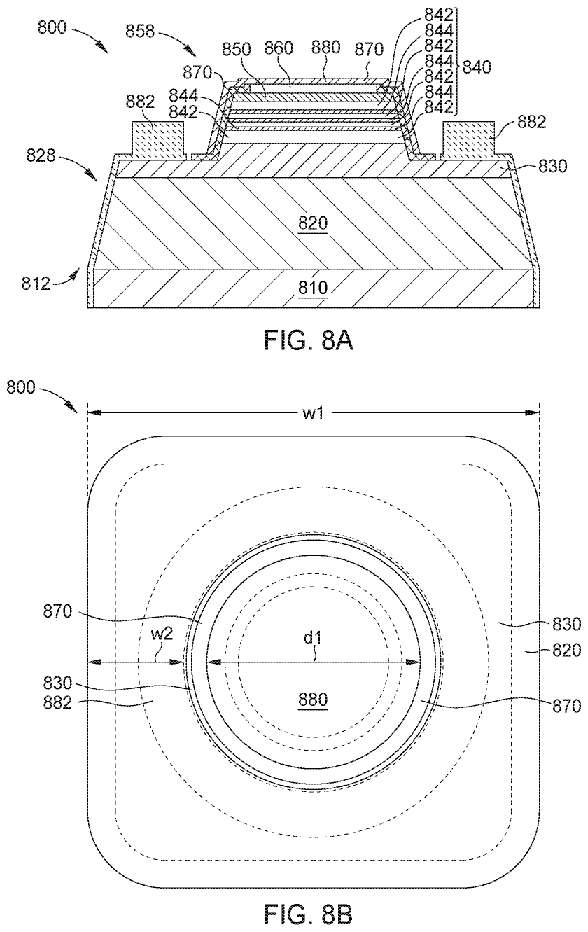

FIGS. 8A and 8B depict a cross-sectional view and a top view, respectively, of a micro-LED device 800 with coaxial contacts, according to one or more embodiments described and discussed herein. For example, FIGS. 8A-8B depict the micro-LED device 800 containing a p-contact which may cover the whole mesa including the mesa sidewall, and n-contact may cover the whole die sidewall, to form as a second mirror, so light extraction efficiency can be further improved, according to one or more embodiments described and discussed herein.

In one or more embodiments, as depicted in FIGS. 8A-8B, a micro-LED device 800 (e.g., processed workpiece) is provided and contains a layered stack 812 disposed on a substrate 810. The substrate 810 and the layered stack 812 may be the same substrate and contain the same layers and/or materials as described and discussed above in generally, as well as for the substrate 210 and the layered stack 212. The layered stack 812 contains a gallium nitride support layer 820 disposed on the substrate 810, an n-doped gallium nitride layer 830 disposed on the gallium nitride support layer 820, a quantum well region 840 disposed on the n-doped gallium nitride layer 830, the quantum well region 840 may contain alternating layers of indium gallium nitride wells 842 and gallium nitride barriers 844.

A p-doped gallium nitride layer 850 may be deposited or otherwise disposed on the quantum well region 840. The micro-LED device 800 also contains a first mesa structure 858 containing at least a first portion of the layered stack 812, where at least the p-doped gallium nitride layer 850, the quantum well region 840, and an upper portion of the n-doped gallium nitride layer 830 form the first mesa structure 858. The micro-LED device 800 also contains a TCO layer 860 disposed on at least a portion of the p-doped gallium nitride layer 850, and a second mesa structure 828 containing at least a second portion of the layered stack 812. At least a lower portion of the n-doped gallium nitride layer 830 and the gallium nitride support layer 820 form the second mesa structure 828. The micro-LED device 800 also contains a dielectric passivation layer 870 disposed on a first portion of the first mesa structure 858 and a first portion of the second mesa structure 828, a revealed portion of the TCO layer 860 in the first mesa structure 858 is free or substantially free of the dielectric passivation layer 870, a revealed portion of the n-doped gallium nitride layer 830 in the second mesa structure 828 is free or substantially free of the dielectric passivation layer 870, and a p-contact layer 880 disposed on the revealed portion of the TCO layer 860 and an n-contact layer 882 disposed on the revealed portion of the n-doped gallium nitride layer 830.

In the embodiments described and discussed herein, the n-doped gallium nitride layer 830, the quantum well region 840, the p-doped gallium nitride layer 850, the TCO layer 860, the dielectric passivation layer 870, the p-contact layer 880, and the n-contact layer 882 may be or contain the same layers and/or materials as described and discussed above, as well as fabricated, produced, or otherwise formed by the same methods and process as described and discussed above in generally, as well as for the n-doped gallium nitride layer 230, the quantum well region 240, the p-doped gallium nitride layer 250, the TCO layer 260, the dielectric passivation layer 270, the p-contact layer 280, and the n-contact layer 282, respectively. Also, the first mesa structure 858 and the second mesa structure 828 may be fabricated, produced, or otherwise formed by the same methods and process as described and discussed above in generally, as well as for forming the first mesa structure 258 and the second mesa structure 228.

In some embodiments, the micro-LED device 800 may contain the p-contact layer 880 and the n-contact layer 882 which are coaxial with each other. In some examples, the p-contact layer 880 has a circular geometry, the n-contact layer 882 has a ring geometry, and the n-contact layer 882 encompasses the p-contact 880. In one or more embodiments, the p-contact layer 880 has a diameter d1, and the n-contact layer 882 has an outer width w1 and an inner width of w2, measured as illustrated in FIG. 8B. In one or more examples, the diameter d1 of the p-contact layer 880 may be in a range from about 5 μm to about 30 μm, such as about 8 μm to about 28 μm, or about 10 μm to about 25 μm, about 15 μm to about 20 μm. In one or more examples, the outer width w1 of the n-contact layer 882 may be in a range from about 20 μm to about 50 μm, such as about 25 μm to about 50 μm, about 30 μm to about 50 μm, about 35 μm to about 50 μm, about 40 μm to about 50 μm, or about 45 μm to about 50 μm. In one or more examples, the inner width of w2 of the n-contact layer 882 may be in a range from about 5 μm to about 20 μm, such as about 6 μm to about 18 μm, or about 7 μm to about 15 μm, about 8 μm to about 12 μm.

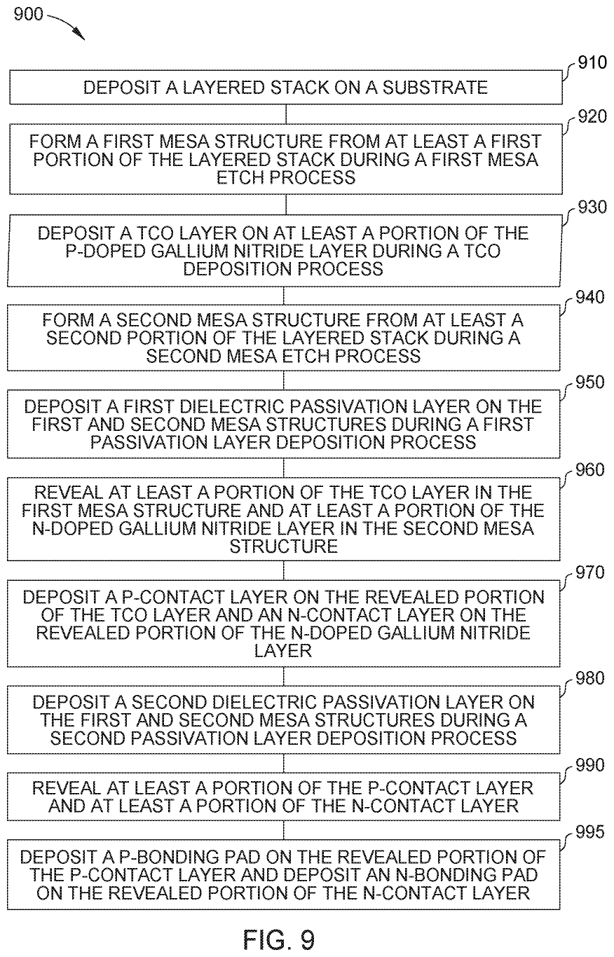

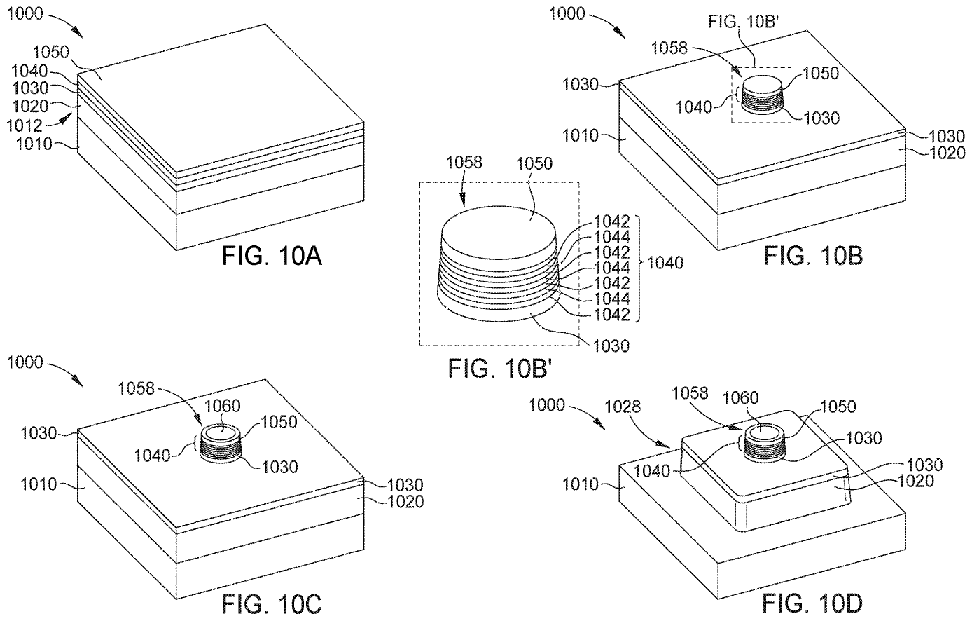

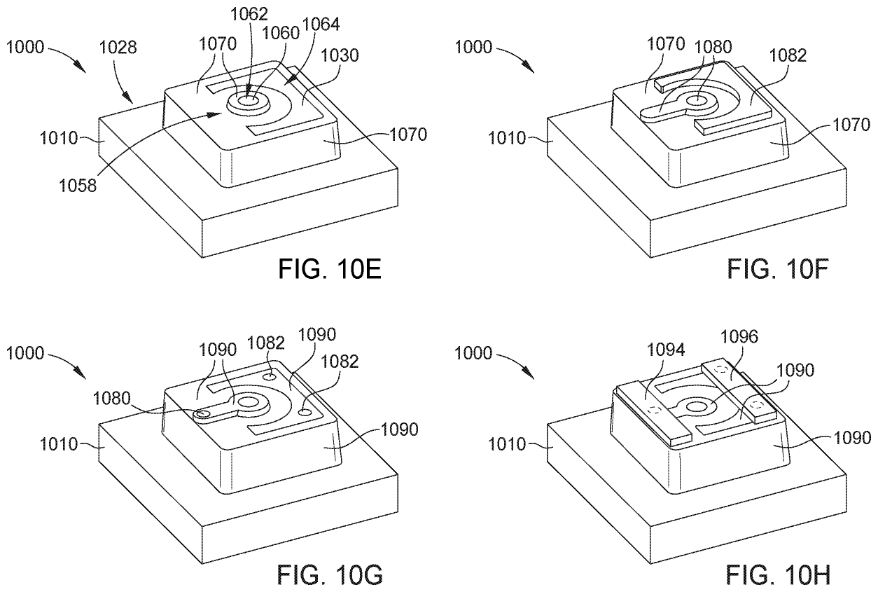

FIG. 9 is a flowchart which includes a method 900 (e.g., flow process) for producing a micro-LED device, according to one or more embodiments described and discussed herein. The method 900 includes operations 910-995, as further described and discussed below. FIGS. 10A-10H depict a cross-sectional view of a workpiece 1000 at different time intervals passing through a flow process for manufacturing, forming, or otherwise producing one or more different types of micro-LED devices with coaxial contacts, the flow process may be such as the method 900 illustrated in FIG. 9, according to one or more embodiments described and discussed herein. The method 900, and variations thereof, may also be followed to produce other type of micro-LED devices, shown and not shown, in embodiments described and discussed herein.

In one or more embodiments, the method 900 for producing micro-LED devices at operation 910, illustrated in FIG. 9, is provided and includes depositing a layered stack 1012 on a substrate 1010, as depicted by the workpiece 1000 in FIG. 10A. The layered stack 1012 may contain a gallium nitride support layer 1020 disposed on the substrate 1010, an n-doped gallium nitride layer 1030 disposed on the gallium nitride support layer 1020, a quantum well region 1040 disposed on the n-doped gallium nitride layer 1030. A p-doped gallium nitride layer 1050 may be deposited or otherwise disposed on the quantum well region 1040 at operation 910. The quantum well region 1040 contains alternating layers of indium gallium nitride wells 1042 and gallium nitride barriers 1044, as depicted in FIG. 10B′. The method 900 at operation 920 also includes forming a first mesa structure 1058 from at least a first portion of the layered stack 1012 during a first mesa etch process, as depicted in FIG. 10B. At least the p-doped gallium nitride layer 1050, the quantum well region 1040, and an upper portion of the n-doped gallium nitride layer 1030 are etched away to form the first mesa structure 1058. The method 900 at operation 930 further includes depositing a TCO layer 1060 on at least a portion of the p-doped gallium nitride layer 1050 during a TCO deposition process, as depicted in FIG. 10C. The method 900 at operation 940 also includes forming a second mesa structure 1028 from at least a second portion of the layered stack 1012 during a second mesa etch process, as depicted in FIG. 10D. At least a lower portion of the n-doped gallium nitride layer 1030 and the gallium nitride support layer 1020 are etched away to form the second mesa structure 1028. The method 900 at operation 950 also includes depositing a first dielectric passivation layer 1070 on the first and second mesa structures 1058, 1028 during a passivation layer deposition process, and at operation 960, revealing at least a portion of the TCO layer 1060 in the first mesa structure 1058 to form a revealed portion 1062 of the TCO layer 1060 and revealing at least a portion of the n-doped gallium nitride layer 1030 in the second mesa structure 1028 to form a revealed portion 1072 of the n-doped gallium nitride layer 1030, as depicted in FIG. 10E. The method 900 at operation 970 also includes depositing a p-contact layer 1080 on the revealed portion 1062 of the TCO layer 1060 and an n-contact layer 1082 on the revealed portion 1064 of the n-doped gallium nitride layer 1030, as depicted in FIG. 10F. The method 900 further includes depositing a second dielectric passivation layer 1090 on the first and second mesa structures 1058, 1028 during a second passivation layer deposition process at operation 980 and revealing at least a portion of the p-contact layer 1080 (e.g., the revealed portion 1080) and at least a portion of the n-contact layer 1082 at operation 990 (e.g., the revealed portion 1082), as depicted in FIG. 10G. The method 900 at operation 995 also includes depositing a p-bonding pad 1094 on the revealed portion (labeled as 1080) of the p-contact layer 1080 and a first portion of the second dielectric passivation layer 1090 and depositing an n-bonding pad 1096 on the revealed portion (labeled as 1082) of the n-contact layer 1082 and a second portion of the second dielectric passivation layer 1090, as depicted in FIG. 10H.

In one or more embodiments, the substrate 1010 may be or contain one or more materials, such as sapphire, silicon, silicon carbide, silicon germanium, silicon-containing compounds, dopants thereof, or any combination thereof. The substrate may be or have any type of geometry, including rounded or squared shapes, such as a circle, a square, a rectangular, or other shapes or geometries. In some embodiments, the substrate 1010 has a thickness in a range from about 50 μm to about 500 μm, such as about 50 μm to about 400 μm, about 100 μm to about 300 μm, or about 150 μm to about 200 μm.

In one or more embodiments, the gallium nitride support layer 1020 may be or contain gallium nitride having high purity and none or substantially no dopants (e.g., undoped gallium nitride). In some examples, the gallium nitride support layer 1020 may be or contain gallium nitride having a purity in a range from about 95 at % to about 100 at %, from about 96 at % to about 100 at %, from about 97 at % to about 100 at %, from about 98 at % to about 100 at %, from about 99 at % to about 100 at %, from about 99.5 at % to about 100 at %, from about 99.9 at % to about 100 at %, from about 99.99 at % to about 100 at %, or purer. In one or more examples, the gallium nitride support layer 1020 contain gallium nitride and is completely or substantially free of a dopant. The gallium nitride support layer 1020 may be deposited by one or more epitaxy processes. In one or more embodiments, the gallium nitride support layer 1020 may have a thickness in a range from about 50 nm to about 5,000 nm, such as about 100 nm to about 4,500 nm, about 150 nm to about 4,000 nm, or about 200 nm to about 3,000 nm.

In one or more embodiments, the n-doped gallium nitride layer 1030 may contain gallium nitride and one or more dopants selected from silicon, germanium, oxygen, sulfur, or any combination thereof. The n-doped gallium nitride layer 1030 may be deposited by one or more epitaxy processes. In one or more embodiments, the n-doped gallium nitride layer 1030 may have a thickness in a range from about 500 nm to about 5,000 nm, about 800 nm to about 4,500 nm, about 1,000 nm to about 4,000 nm, about 1,200 nm to about 3,000 nm, or about 1,500 nm to about 2,500 nm.

In one or more embodiments, the quantum well region 1040 may contain one or multiple pairs of the alternating layers of indium gallium nitride wells 1042 and gallium nitride barriers 1044. In some examples, the quantum well region 1040 may contain 1 pair, 2 pairs, 3 pairs, 4 pairs, 5 pairs, 6 pairs, or more of the alternating layers of indium gallium nitride wells 1042 and gallium nitride barriers 1044. Each of the alternating layers of indium gallium nitride wells 1042 and gallium nitride barriers 1044 may independently be deposited by one or more epitaxy processes. In some examples, the quantum well region 1040 layer may have a thickness in a range from about 3 nm to about 50 nm, about 3 nm to about 40 nm, about 4 nm to about 30 nm, or about 5 nm to about 20 nm. In one or more examples, each of the indium gallium nitride well layers 242 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm. In some examples, each of the gallium nitride barrier layers 244 may have a thickness in a range from about 2 nm to about 5 nm, about 2.5 nm to about 5 nm, about 2.5 nm to about 4 nm, about 2.5 nm to about 3.5 nm, or about 2.7 nm to about 3 nm.

In some embodiments, the quantum well region 1040 (InGaN/GaN) may be or contain multiple quantum wells (MQWs) or a single MQW of alternating nano-layers (e.g., alternating layers of indium gallium nitride wells 1042 and gallium nitride barriers 1044) acting as the active region in blue/green LEDs and lasers, providing high-efficiency light emission, and/or wavelength tuning. In some examples, the MQW structures, may have 3, 4, 5 or more periods, utilize GaN barriers to confine carriers within InGaN wells, with growth optimized to reduce defect density. In some examples, performance is may be improved by Si-doping the GaN barriers to prevent structural degradation. In one or more examples, the alternating thin layers (e.g., several nanometers) may be or contain indium gallium nitride (InₓGa₍₁₋ₓ₎N) and gallium nitride (GaN). The lower bandgap InGaN acts as the quantum well for carrier trapping, while the wider bandgap GaN serves as the barrier.

In one or more embodiments, the p-doped gallium nitride layer 1050 may contain gallium nitride and one or more dopants selected from magnesium, beryllium, zinc, carbon, or any combination thereof. The p-doped gallium nitride layer 1050 may be deposited by one or more epitaxy processes. In one or more embodiments, the p-doped gallium nitride layer 1050 may have a thickness in a range from about 10 nm to about 400 nm, about 10 nm to about 350 nm, about 15 nm to about 300 nm, or about 20 nm to about 250 nm.

In one or more embodiments, the first mesa structure 1058 may be produced or otherwise formed during the first mesa etch process at operation 920. The first mesa etch process may include exposing the first portion of the layered stack 1012 to photolithography and at least one or more etches, such as one or more reactive ion etches, one or more dry etches, one or more wet etches, or any combination thereof. The first mesa structure 1058 contains angled sides outwardly sloping from the p-doped gallium nitride layer 1050 to the n-doped gallium nitride layer 1030. In some examples, the first mesa structure 1058 may have a lateral width in a range from about 1 μm, about 2 μm, about 3 μm, about 4 μm, or about 5 μm to about 6 μm, about 7 μm, about 8 μm, about 9 μm, or about 10 μm, for example, in a range from about 1 μm to about 10 μm, about 2 μm to about 8 μm, or about 3 μm to about 6 μm.

In one or more examples, a dry etch may employ during the first mesa etch process at operation 920 and include halogen-based etch chemistries selected to etch Group III-V semiconductor materials and/or Group III-nitride semiconductor materials, including one or more chlorine-containing compounds and/or gases, one or more bromine-based compounds and/or gases, or any combination thereof. By way of non-limiting example, the etch chemistry may be or contain one or more chlorine (Cl₂), boron trichloride (BCl₃), silicon tetrachloride (SiCl₄), hydrogen chloride (HCl), argon (Ar), gases thereof, plasmas thereof, or any combination thereof. The etch chemistry and process provides or otherwise forms the mesa with substantially vertical sidewalls. In one or more embodiments, the first mesa etch controls a sidewall profile of the mesa structure. For example, the process parameters of the plasma etching, such as ion energy, plasma density, chamber pressure, and/or gas composition, may be selected to achieve a substantially anisotropic etch, thereby defining mesa sidewalls having a controlled angle relative to a surface of the wafer. In some embodiments, the mesa sidewall angle of the first mesa structure 1058 may be in a range from about 45°, about 48°, about 50°, or about 52° to about 55°, about 58°, about 60°, about 62°, about 65°, about 68°, or about 70°. The mesa sidewall angle may be advantageous for reducing electrical leakage, improving current confinement, and enhancing optical extraction or waveguide coupling efficiency in photonic interconnect applications. In one or more embodiments, the first mesa etch process may further include one or more post-etch treatments to reduce or eliminate plasma-induced damage and contamination on mesa sidewalls. In some examples, the post-etch treatments may be or include oxygen-containing plasma treatments, hydrogen-containing plasma treatments, one or more wet cleaning processes (e.g., acid-based clean or alkaline-based clean), or combinations thereof. The post-etch treatments may remove etch residues, redeposited material, or damaged surface layers.

In one or more examples, the first mesa etch process at operation 920 may be a “die isolation” process (also known as mesa etching or device isolation) which may be used as a material-removal step to define individual LED chips and electrically separate them on a wafer. The first mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, a mesa etch process may be used to expose two different surfaces in the LED epilayer that may be coupled to corresponding electrodes or electrical contacts. For example, the mesa process may expose a p-doped GaN surface on one portion of the LED epilayer. By etching away a portion of the p-doped GaN surface (along with any intervening layers, such as an MQW region), a portion of an underlying n-doped GaN layer may be exposed to form an n-doped GaN surface. Any type of etch process may be used to expose these surfaces, including photolithography, reactive ion etches, and other etching processes.

In one or more embodiments, the TCO layer 1060 may be or contain indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof. In one or more examples, the TCO layer 1060 may be or contain ITO. The TCO layer 1060 is deposited by a sputtering process, a PVD process, a CVD process, an ALD process, other deposition processes, or any combination thereof during the operation 930. In some examples, the TCO layer 1060 may have a thickness in a range from about 10 nm to about 500 nm, such as about 10 nm to about 200 nm, about 10 nm to about 150 nm, or about 10 nm to about 120 nm. In one or more examples, the TCO layer 1060 may have a diameter in a range from about 1 μm to about 50 μm, such as about 1 μm to about 20 μm, about 1 μm to about 10 μm, about 1 μm to about 5 μm, or about 1 μm to about 3 μm.

In one or more embodiments, the second mesa structure 1028 is produced or otherwise formed during the second mesa etch process at operation 940. The second mesa etch process may include exposing the lower portion of the n-doped gallium nitride layer 1030 and the gallium nitride support layer 1020 to photolithography and at least one or more etches, such as one or more reactive ion etches, one or more dry etches, one or more wet etches, or any combination thereof. In some examples, the second mesa structure 1028 may have a lateral width in a range from about 1 μm, about 2 μm, about 3 μm, about 5 μm, about 8 μm, about 10 μm, about 15 μm, about 20 μm, about 25 μm, about 30 μm, about 35 μm, about 40 μm, about 45 μm, about 50 μm, or about 60 μm, or greater. For example, the second mesa structure 228 may have a lateral width in a range from about 1 μm to about 50 μm, about 5 μm to about 50 μm, about 5 μm to about 40 μm, about 10 μm to about 50 μm, or about 10 μm to about 30 μm.

In one or more embodiments, the second mesa etch process at operation 940 may be utilized for etching to a depth sufficient to physically isolate neighboring micro-LED devices. The etch depth may be controlled using timed etching, endpoint detection, and/or process margin to ensure an isolation trench between adjacent dies. In some embodiments, the second mesa etch defines isolation trench sidewalls with a profile which is completely vertical or substantially vertical and maintains mechanical integrity of the micro-LED array. In some embodiments, the mesa sidewall angle of the second mesa structure 1028 may be in a range from about 70°, about 72°, about 75°, or about 78° to about 80°, about 82°, about 85°, about 87°, about 88°, or about 90°. The mesa sidewall angle of the second mesa structure 1028 may be advantageous for enhancing optical extraction and/or waveguide coupling efficiency in photonic interconnect applications. Following the second mesa etch process, residual etch byproducts or damaged surface regions may be removed using one or more post-etch treatments to improve electrical isolation and device reliability. In one or more examples, the mesa sidewall angle of the second mesa structure 1028 may be greater than the mesa sidewall angle of the first mesa structure 1058.

In one or more examples, the second mesa etch process at operation 940 may be a “die isolation” process (also known as mesa etching or device isolation) which may be used as a material-removal step to define individual LED chips and electrically separate them on a wafer. The second mesa etch process may remove specific layers of the semiconductor or epitaxial material to prevent electrical crosstalk and current leakage between adjacent devices. In some examples, common die isolation techniques include: plasma etching, laser ablation, stealth dicing, or any combination thereof. Exemplary plasma etching (mesa etching) may be or include inductively coupled plasma (ICP) or reactive ion etching (RIE) to define the LED mesa by removing the excess active region. Plasma etching process forms a physical gap (trench) between the individual LED structures. Exemplary laser ablation may include a high-energy laser which melts and/or evaporates material to create a full cut or deep groove between dies. Exemplary stealth dicing may include a “dry” singulation method where a laser forms modification layers inside the material without removing surface material initially, thereafter, the dies may be later separated by stretching a carrier tape.

In one or more embodiments, the first dielectric passivation layer 1070 may be or contain one or more dielectric materials, such as aluminum oxide, silicon oxide, hafnium oxide, silicon nitride, silicon oxynitride, hafnium silicate, dopants thereof, or any combination thereof. The first dielectric passivation layer 1070 may be deposited at operation 950 by a CVD process, a PE-CVD process, an ALD process, a PE-ALD process, other deposition processes, or any combination thereof. In some examples, the first dielectric passivation layer 1070 may have a thickness in a range from about 5 nm to about 250 nm, about 5 nm to about 150 nm, or about 10 nm to about 100 nm.

In one or more embodiments, the method 900 further includes revealing the portion of the TCO layer 1060 in the first mesa structure 1058 and/or revealing the portion of the n-doped gallium nitride layer 1030 in the second mesa structure 1028 at operation 960. In some embodiments, the method 900 may further include one or more photolithography processes, one or more etch processes, or any combination thereof at operation 960. For example, photolithography and at least one or more etches, such as one or more reactive ion etches, one or more dry etches, one or more wet etches, or any combination thereof may be used to reveal the portion of the TCO layer 1060 in the first mesa structure 1058 and/or reveal the portion of the n-doped gallium nitride layer 1030 in the second mesa structure 1028.

In one or more embodiments, each of the p-contact layer 1080 and the n-contact layer 1082 may independently be or contain one or more metals, such as titanium, nickel, aluminum, rhodium, platinum, silver, gold, copper, chromium, tungsten, alloys thereof, dopants thereof, or any combination thereof. In some embodiments, each of the p-contact layer 1080 and the n-contact layer 1082 may independently be or contain a metal stack. Each metal stack may be or contain two, three, four, five, or more metal layers where each metal layer may be or contain a different composition relative to the other layers in the metal stack. In some examples, each metal layer may independently be or contain titanium, nickel, aluminum, rhodium, platinum, silver, gold, copper, chromium, tungsten, alloys thereof, dopants thereof, or any combination thereof. In one or more examples the metal stack may contain a first layer containing chromium, a second layer containing aluminum, a third layer containing nickel, and a fourth layer containing gold, such the fourth layer is disposed on the third layer, which is disposed on the second layer, which is disposed on the first layer (e.g., Cr/Al/Ti/Ni/Au). In other examples, the metal stack may contain a first layer containing chromium, a second layer containing platinum, and a third layer containing gold, such the third layer is disposed on the second layer, which is disposed on the first layer (e.g., Cr/Pt/Au). Each of the p-contact layer 1080 and the n-contact layer 1082 may be independently deposited or otherwise formed by one or more of a sputtering process, a thermal evaporation process, an electron beam (e-beam) process, an electroplating process, a PVD process, a CVD process, a PE-CVD process, an ALD process, a PE-ALD process, other deposition processes, or any combination thereof.

In one or more embodiments, the p-contact layer 1080 may have a first portion with a circular geometry and a second portion radially extending away from the circumference of the first portion, as illustrated in FIG. 10F. The n-contact layer 1082 may have a geometry to partially or substantially surround or encompass a minority or majority of the circumference of the first portion of the p-contact layer 1080, as illustrated in FIG. 10F. In other embodiments, the p-contact layer 1080 has a circular geometry, the n-contact layer 1082 may have a ring geometry, and the n-contact layer 1082 is coaxial to and encompasses the p-contact layer 1080. In some examples, the first portion of the p-contact layer 1080 may have a diameter in a range from about 1 μm to about 50 μm and a thickness in a range from about 100 nm to about 1 μm. In other embodiments, the n-contact layer 1082 may have a width in a range from about 1 μm to about 50 μm, a thickness in a range from about 100 nm to about 1 μm, and an inner diameter of the ring geometry in a range from about 10 μm to about 200 μm.

In one or more embodiments, the second dielectric passivation layer 1090 may be or contain one or more dielectric materials, such as aluminum oxide, silicon oxide, hafnium oxide, silicon nitride, silicon oxynitride, hafnium silicate, dopants thereof, or any combination thereof. The second dielectric passivation layer 1090 may be deposited at operation 980 by a CVD process, a PE-CVD process, an ALD process, a PE-ALD process, other deposition processes, or any combination thereof. In some examples, the second dielectric passivation layer 1090 may have a thickness in a range from about 5 nm to about 250 nm, about 5 nm to about 150 nm, or about 10 nm to about 100 nm.

In one or more embodiments, the method 900 further includes revealing the portion of the p-contact layer 1080 and a first portion of the second dielectric passivation layer 1090 and/or revealing the portion of the n-contact layer 1082 and a second portion of the second dielectric passivation layer 1090 at operation 990. In some embodiments, the method 900 may further include one or more photolithography processes, one or more etch processes, or any combination thereof at operation 990. For example, photolithography and at least one or more etches, such as one or more reactive ion etches, one or more dry etches, one or more wet etches, or any combination thereof may be used to reveal the portion of the p-contact layer 1080 and a first portion of the second dielectric passivation layer 1090 and/or the portion of the n-contact layer 1082 and a second portion of the second dielectric passivation layer 1090 at operation 990.

In one or more embodiments, each of the p-bonding pad 1094 and the n-bonding pad 1096 may independently be or contain one or more metals, such as titanium, nickel, aluminum, rhodium, platinum, silver, gold, copper, chromium, tungsten, alloys thereof, dopants thereof, or any combination thereof. In some embodiments, each of the p-bonding pad 1094 and the n-bonding pad 1096 may independently be or contain a metal stack. Each metal stack may be or contain two, three, four, five, or more metal layers where each metal layer may be or contain a different composition relative to the other layers in the metal stack. In some examples, each metal layer may independently be or contain titanium, nickel, aluminum, rhodium, platinum, silver, gold, copper, chromium, tungsten, alloys thereof, dopants thereof, or any combination thereof. In one or more examples the metal stack may contain a first layer containing chromium, a second layer containing aluminum, a third layer containing nickel, and a fourth layer containing gold, such the fourth layer is disposed on the third layer, which is disposed on the second layer, which is disposed on the first layer (e.g., Cr/Al/Ti/Ni/Au). In other examples, the metal stack may contain a first layer containing chromium, a second layer containing platinum, and a third layer containing gold, such the third layer is disposed on the second layer, which is disposed on the first layer (e.g., Cr/Pt/Au). Each of the p-bonding pad 1094 and the n-bonding pad 1096 may be independently have a length in a range from about 5 μm to about 50 μm, such as about 10 μm to about 40 μm; a width in a range from about 1 μm to about 10 μm, such as about 2 μm to about 8 μm; and a thickness in a range from about 0.2 μm to about 5 μm, such as about 0.5 μm to about 4 μm. Each of the p-bonding pad 1094 and the n-bonding pad 1096 may be independently deposited or otherwise formed by one or more of a sputtering process, a thermal evaporation process, an electron beam (e-beam) process, an electroplating process, a PVD process, a CVD process, a PE-CVD process, an ALD process, a PE-ALD process, other deposition processes, or any combination thereof.

In one or more embodiments, as depicted in FIG. 10H, a micro-LED device 1000 (e.g., processed workpiece) is provided and contains a layered stack 1012 disposed on a substrate 1010. The layered stack 1012 contains a gallium nitride support layer 1020 disposed on the substrate 1010, an n-doped gallium nitride layer 1030 disposed on the gallium nitride support layer 1020, a quantum well region 1040 disposed on the n-doped gallium nitride layer 1030, the quantum well region 1040 may contain alternating layers of indium gallium nitride wells 1042 and gallium nitride barriers 1044. A p-doped gallium nitride layer 1050 may be deposited or otherwise disposed on the quantum well region 1040. The micro-LED device 1000 also contains a first mesa structure 1058 containing at least a first portion of the layered stack 1012, wherein at least the p-doped gallium nitride layer 1050, the quantum well region 1040, and an upper portion of the n-doped gallium nitride layer 1030 form the first mesa structure 1058. The micro-LED device also contains a TCO layer 1060 disposed on at least a portion of the p-doped gallium nitride layer 1050, and a second mesa structure 1028 containing at least a second portion of the layered stack 1012. At least a lower portion of the n-doped gallium nitride layer 1030 and the gallium nitride support layer 1020 form the second mesa structure 1028. The micro-LED device 1000 also contains a first dielectric passivation layer 1070 disposed on a first portion of the first mesa structure 1058 and a first portion of the second mesa structure 1028, a revealed portion of the TCO layer 1060 in the first mesa structure 1058 is free or substantially free of the first dielectric passivation layer 1070, a revealed portion of the n-doped gallium nitride layer 1030 in the second mesa structure 1028 is free or substantially free of the first dielectric passivation layer 1070, and a p-contact layer 1080 disposed on the revealed portion of the TCO layer 1060 and an n-contact layer 1082 disposed on the revealed portion of the n-doped gallium nitride layer 1030. The micro-LED device 1000 also contains a second dielectric passivation layer 1090 on the first and second mesa structures 1058, 1028 and a revealed portion of the p-contact layer 1080 (e.g., the revealed portion 1080) and a revealed portion of the n-contact layer 1082 (e.g., the revealed portion 1082). A p-bonding pad 1094 is disposed on the revealed portion of the p-contact layer 1080 and a first portion of the second dielectric passivation layer 1090. An n-bonding pad 1096 is disposed on the revealed portion of the n-contact layer 1082 and a second portion of the second dielectric passivation layer 1090.

### Exemplary Embodiments

The present disclosure provides, among others, the following embodiments, each of which may be considered as optionally including any alternate embodiments per one or more of the following Clauses contained in Clause Groups 1-3. Any one or more Clauses within Clause Group 1, 2, or 3 may be combined with any one or more Clauses within any one or more of Clause Group 1, 2, or 3. The Clause Groups 1-3 are as follows:

### Clause Group 1 Containing the Following Clauses 1-39

Clause 1. A method for producing a micro-LED device, comprising: depositing a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; forming a first mesa structure from at least a first portion of the layered stack during a first mesa etch process, wherein at least the p-doped gallium nitride layer, the quantum well region, and an upper portion of the n-doped gallium nitride layer are etched away to form the first mesa structure; depositing a TCO layer on at least a portion of the p-doped gallium nitride layer during a TCO deposition process; forming a second mesa structure from at least a second portion of the layered stack during a second mesa etch process, wherein at least a lower portion of the n-doped gallium nitride layer and the gallium nitride support layer are etched away to form the second mesa structure; depositing a dielectric passivation layer on the first and second mesa structures during a passivation layer deposition process; revealing at least a portion of the TCO layer in the first mesa structure to form a revealed portion of the TCO layer and revealing at least a portion of the n-doped gallium nitride layer in the second mesa structure to form a revealed portion of the n-doped gallium nitride layer; and depositing a p-contact layer on the revealed portion of the TCO layer and an n-contact layer on the revealed portion of the n-doped gallium nitride layer.

Clause 2. A micro-LED device, comprising: a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; a first mesa structure comprising at least a first portion of the layered stack, wherein at least the p-doped gallium nitride layer, the quantum well region, and an upper portion of the n-doped gallium nitride layer form the first mesa structure; a TCO layer disposed on at least a portion of the p-doped gallium nitride layer; a second mesa structure comprising at least a second portion of the layered stack, wherein at least a lower portion of the n-doped gallium nitride layer and the gallium nitride support layer form the second mesa structure; a dielectric passivation layer disposed on a first portion of the first mesa structure and a first portion of the second mesa structure; a revealed portion of the TCO layer in the first mesa structure is free or substantially free of the dielectric passivation layer; a revealed portion of the n-doped gallium nitride layer in the second mesa structure is free or substantially free of the dielectric passivation layer; and a p-contact layer disposed on the revealed portion of the TCO layer and an n-contact layer disposed on the revealed portion of the n-doped gallium nitride layer.

Clause 3. The method and/or the micro-LED device according to claim 1 or 2, wherein the p-contact layer has a circular geometry, the n-contact layer has a ring geometry, and the n-contact layer is coaxial to and encompasses the p-contact layer.

Clause 4. The method and/or the micro-LED device according to any one of Clauses 1-3, wherein the p-contact layer has a diameter in a range from about 1 μm to about 50 μm and a thickness in a range from about 100 nm to about 1 μm.

Clause 5. The method and/or the micro-LED device according to any one of Clauses 1-4, wherein the n-contact layer has a ring geometry, wherein the n-contact layer has a width in a range from about 1 μm to about 50 μm, a thickness in a range from about 100 nm to about 1 μm, and an outer diameter of the ring geometry in a range from about 10 μm to about 200 μm.

Clause 6. The method and/or the micro-LED device according to any one of Clauses 1-5, wherein each of the p-contact layer and the n-contact layer independently comprises a metal comprising titanium, nickel, aluminum, rhodium, platinum, silver, gold, copper, chromium, tungsten, alloys thereof, or any combination thereof.

Clause 7. The method and/or the micro-LED device according to any one of Clauses 1-6, wherein each of the p-contact layer and the n-contact layer independently comprises a metal stack, wherein each metal stack comprises three or more metal layers of different compositions, and wherein each metal layer comprises titanium, nickel, aluminum, rhodium, platinum, silver, gold, copper, chromium, tungsten, alloys thereof, or any combination thereof, For example, and/or wherein some examples, each metal stack comprises Cr/Al/Ti/Ni/Au or Cr/Pt/Au.

Clause 8. The method and/or the micro-LED device according to any one of Clauses 1-7, wherein each of the p-contact layer and the n-contact layer is independently deposited by one or more of a sputtering process, a thermal evaporation process, an electron beam (e-beam) process, an electroplating process, a physical vapor deposition (PVD) process, a chemical vapor deposition (CVD) process, a plasma-enhanced CVD (PE-CVD) process, an atomic layer deposition (ALD) process, a plasma-enhanced ALD (PE-ALD) process, or any combination thereof.

Clause 9. The method and/or the micro-LED device according to any one of Clauses 1-8, wherein the substrate comprises one or more of sapphire, silicon, silicon carbide, dopants thereof, or any combination thereof.

Clause 10. The method and/or the micro-LED device according to any one of Clauses 1-9, wherein the substrate has a thickness in a range from about 50 μm to about 500 μm, for example about 150 μm to about 200 μm.

Clause 11. The method and/or the micro-LED device according to any one of Clauses 1-10, wherein the gallium nitride support layer comprises gallium nitride having a purity in a range from about 95 at % to about 100 at %, such as undoped GaN.

Clause 12. The method and/or the micro-LED device according to any one of Clauses 1-11, wherein the gallium nitride support layer comprises gallium nitride and is completely or substantially free of a dopant.

Clause 13. The method and/or the micro-LED device according to any one of Clauses 1-12, wherein the gallium nitride support layer is deposited by an epitaxy process.

Clause 14. The method and/or the micro-LED device according to any one of Clauses 1-13, wherein the gallium nitride support layer has a thickness in a range from about 50 nm to about 5,000 nm, such as about 200 nm to about 3,000 nm.

Clause 15. The method and/or the micro-LED device according to any one of Clauses 1-14, wherein the n-doped gallium nitride layer comprises gallium nitride and one or more dopants selected from silicon, germanium, oxygen, or any combination thereof.

Clause 16. The method and/or the micro-LED device according to any one of Clauses 1-15, wherein the n-doped gallium nitride layer has a thickness in a range from about 500 nm to about 5,000 nm, such as about 1,500 nm to about 2,500 nm.

Clause 17. The method and/or the micro-LED device according to any one of Clauses 1-16, wherein the n-doped gallium nitride layer is deposited by an epitaxy process.

Clause 18. The method and/or the micro-LED device according to any one of Clauses 1-17, wherein the quantum well region comprises in a range from about 1 pair to about 5 pairs of the alternating layers of indium gallium nitride wells and gallium nitride barriers.

Clause 19. The method and/or the micro-LED device according to any one of Clauses 1-18, wherein the quantum well region layer has a thickness in a range from about 3 nm to about 50 nm, such as about 5 nm to about 20 nm.

Clause 20. The method and/or the micro-LED device according to any one of Clauses 1-19, wherein the alternating layers of indium gallium nitride wells and gallium nitride barriers are deposited by an epitaxy process.

Clause 21. The method and/or the micro-LED device according to any one of Clauses 1-20, wherein each of the indium gallium nitride well layers has a thickness in a range from about 2 nm to about 5 nm, such as about 2.7 nm to about 3 nm.

Clause 22. The method and/or the micro-LED device according to any one of Clauses 1-21, wherein each of the gallium nitride barrier layers has a thickness in a range from about 2 nm to about 5 nm, such as about 2.7 nm to about 3 nm.

Clause 23. The method and/or the micro-LED device according to any one of Clauses 1-22, wherein the p-doped gallium nitride layer comprises gallium nitride and one or more dopants selected from magnesium, beryllium, zinc, carbon, or any combination thereof.

Clause 24. The method and/or the micro-LED device according to any one of Clauses 1-23, wherein the p-doped gallium nitride layer has a thickness in a range from about 10 nm to about 400 nm, such as about 20 nm to about 250 nm.

Clause 25. The method and/or the micro-LED device according to any one of Clauses 1-24, wherein the p-doped gallium nitride layer is deposited by an epitaxy process.

Clause 26. The method and/or the micro-LED device according to any one of Clauses 1-25, wherein the first mesa structure has a size in a range from about 1 μm to about 10 μm.

Clause 27. The method and/or the micro-LED device according to any one of Clauses 1-26, wherein the first mesa etch process comprises exposing the first portion of the layered stack to photolithography and at least one of a reactive ion etch, a dry etch, a wet etch, or any combination thereof to form the first mesa structure.

Clause 28. The method and/or the micro-LED device according to any one of Clauses 1-27, wherein the first mesa structure comprises angled sides outwardly sloping from the p-doped gallium nitride layer to the n-doped gallium nitride layer.

Clause 29. The method and/or the micro-LED device according to any one of Clauses 1-28, wherein the TCO layer comprises indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof, such as the TCO layer comprises indium tin oxide.

Clause 30. The method and/or the micro-LED device according to any one of Clauses 1-29, wherein the TCO layer has a thickness in a range from about 10 nm to about 500 nm, such as about 10 nm to about 200 nm, about 10 nm to about 150 nm, or about 10 nm to about 120 nm.

Clause 31. The method and/or the micro-LED device according to any one of Clauses 1-30, wherein the TCO layer has a diameter in a range from about 1 μm to about 50 μm, such as about 1 μm to about 20 μm, about 1 μm to about 10 μm, about 1 μm to about 5 μm, or about 1 μm to about 3 μm.

Clause 32. The method and/or the micro-LED device according to any one of Clauses 1-31, wherein the TCO layer is deposited by a sputtering process, a PVD process, a CVD process, an ALD process, or any combination thereof.

Clause 33. The method and/or the micro-LED device according to any one of Clauses 1-32, wherein the second mesa etch process comprises exposing the lower portion of the n-doped gallium nitride layer and the gallium nitride support layer to photolithography and at least one of a reactive ion etch, a dry etch, a wet etch, or any combination thereof to form the second mesa structure.

Clause 34. The method and/or the micro-LED device according to any one of Clauses 1-33, wherein the second mesa structure has a size in a range from about 1 μm to about 50 μm.

Clause 35. The method and/or the micro-LED device according to any one of Clauses 1-34, wherein the dielectric passivation layer comprises one or more of aluminum oxide, silicon oxide, hafnium oxide, silicon nitride, silicon oxynitride, hafnium silicate, dopants thereof, or any combination thereof.

Clause 36. The method and/or the micro-LED device according to any one of Clauses 1-35, wherein the dielectric passivation layer has a thickness in a range from about 5 nm to about 150 nm.

Clause 37. The method and/or the micro-LED device according to any one of Clauses 1-36, wherein the dielectric passivation layer is deposited by a CVD process, a PE-CVD process, an ALD process, a PE-ALD process, or any combination thereof.

Clause 38. The method and/or the micro-LED device according to any one of Clauses 1-37, wherein revealing the portion of the TCO layer in the first mesa structure further comprises one or more photolithography, one or more etch processes, or any combination thereof.

Clause 39. The method and/or the micro-LED device according to any one of Clauses 1-38, wherein revealing the portion of the n-doped gallium nitride layer in the second mesa structure further comprises one or more photolithography, one or more etch processes, or any combination thereof.

### Clause Group 2 Containing the Following Clauses 1-43

Clause 1. A method for producing a micro-LED device, comprising: depositing a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; forming a first mesa structure from at least a first portion of the layered stack during a first mesa etch process, wherein at least the p-doped gallium nitride layer, the quantum well region, and an upper portion of the n-doped gallium nitride layer are etched away to form the first mesa structure; exposing side surfaces and at least a portion of an upper surface of the first mesa structure to an ion implantation process to produce ion-doped portion of the first mesa structure; depositing a transparent conductive oxide (TCO) layer on at least a portion of the p-doped gallium nitride layer during a TCO deposition process; forming a second mesa structure from at least a second portion of the layered stack during a second mesa etch process, wherein at least a lower portion of the n-doped gallium nitride layer and the gallium nitride support layer are etched away to form the second mesa structure; depositing a dielectric passivation layer on the first and second mesa structures during a passivation layer deposition process; revealing at least a portion of the TCO layer in the first mesa structure to form a revealed portion of the TCO layer and revealing at least a portion of the n-doped gallium nitride layer in the second mesa structure to form a revealed portion of the n-doped gallium nitride layer; and depositing a p-contact layer on the revealed portion of the TCO layer and an n-contact layer on the revealed portion of the n-doped gallium nitride layer.

Clause 2. A micro-LED device, comprising: a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; a first mesa structure comprising at least a first portion of the layered stack, wherein at least the p-doped gallium nitride layer, the quantum well region, and an upper portion of the n-doped gallium nitride layer form the first mesa structure, wherein outside surfaces and at least a portion of an upper surface of the first mesa structure comprises implanted comprise an ion-doped portion of the first mesa structure, and where the ion-doped portion comprises one or more elemental ions selected from hydrogen, helium, boron, carbon, nitrogen, oxygen, fluorine, silicon, phosphorus, argon, chromium, iron, zinc, titanium, or any combination thereof; a TCO layer disposed on at least a portion of the p-doped gallium nitride layer; a second mesa structure comprising at least a second portion of the layered stack, wherein at least a lower portion of the n-doped gallium nitride layer and the gallium nitride support layer form the second mesa structure; a dielectric passivation layer disposed on a first portion of the first mesa structure and a first portion of the second mesa structure; a revealed portion of the TCO layer in the first mesa structure is free or substantially free of the dielectric passivation layer; a revealed portion of the n-doped gallium nitride layer in the second mesa structure is free or substantially free of the dielectric passivation layer; and a p-contact layer disposed on the revealed portion of the TCO layer and an n-contact layer disposed on the revealed portion of the n-doped gallium nitride layer.

Clause 3. The method and/or the micro-LED device according to any one of Clauses 1 or 2, wherein the ion implantation process further comprises exposing the side surfaces and the portion of the upper surface of the first mesa structure to one or more elemental ions via an ion implanter system.

Clause 4. The method and/or the micro-LED device according to any one of Clauses 1-3, wherein the one or more elemental ions are selected from hydrogen, helium, boron, carbon, nitrogen, oxygen, fluorine, silicon, phosphorus, argon, chromium, iron, zinc, titanium, or any combination thereof.

Clause 5. The method and/or the micro-LED device according to any one of Clauses 1-4, wherein the ion implanter system generates an implantation energy in a range from about 10 keV to about 100 keV.

Clause 6. The method and/or the micro-LED device according to any one of Clauses 1-5, wherein the one or more elemental ions penetrate into the side surfaces and the portion of the upper surface of the first mesa structure to a depth in a range from about 200 nm to about 10 μm.

Clause 7. The method and/or the micro-LED device according to any one of Clauses 1-6, wherein the p-contact layer has a circular geometry, the n-contact layer has a ring geometry, and the n-contact layer is coaxial to and encompasses the p-contact layer.

Clause 8. The method and/or the micro-LED device according to any one of Clauses 1-7, wherein the p-contact layer has a diameter in a range from about 1 μm to about 50 μm and a thickness in a range from about 100 nm to about 1 μm.

Clause 9. The method and/or the micro-LED device according to any one of Clauses 1-8, wherein the n-contact layer has a ring geometry, wherein the n-contact layer has a width in a range from about 1 μm to about 50 μm, a thickness in a range from about 100 nm to about 1 μm, and an outer diameter of the ring geometry in a range from about 10 μm to about 200 μm.

Clause 10. The method and/or the micro-LED device according to any one of Clauses 1-9, wherein each of the p-contact layer and the n-contact layer independently comprises a metal comprising titanium, nickel, aluminum, rhodium, platinum, silver, gold, copper, chromium, tungsten, alloys thereof, or any combination thereof.

Clause 11. The method and/or the micro-LED device according to any one of Clauses 1-10, wherein each of the p-contact layer and the n-contact layer independently comprises a metal stack, wherein each metal stack comprises three or more metal layers of different compositions, and wherein each metal layer comprises titanium, nickel, aluminum, rhodium, platinum, silver, gold, copper, chromium, tungsten, alloys thereof, or any combination thereof, and/or wherein some examples, each metal stack comprises Cr/Al/Ti/Ni/Au or Cr/Pt/Au.

Clause 12. The method and/or the micro-LED device according to any one of Clauses 1-11, wherein each of the p-contact layer and the n-contact layer is independently deposited by one or more of a sputtering process, a thermal evaporation process, an electron beam (e-beam) process, an electroplating process, a PVD process, a CVD process, a PE-CVD process, an ALD process, a PE-ALD process, or any combination thereof.

Clause 13. The method and/or the micro-LED device according to any one of Clauses 1-12, wherein the substrate comprises one or more of sapphire, silicon, silicon carbide, dopants thereof, or any combination thereof.

Clause 14. The method and/or the micro-LED device according to any one of Clauses 1-13, wherein the substrate has a thickness in a range from about 50 μm to about 500 μm, such as about 150 μm to about 200 μm.

Clause 15. The method and/or the micro-LED device according to any one of Clauses 1-14, wherein the gallium nitride support layer comprises gallium nitride having a purity in a range from about 95 at % to about 100 at %, in some examples, undoped GaN.

Clause 16. The method and/or the micro-LED device according to any one of Clauses 1-15, wherein the gallium nitride support layer comprises gallium nitride and is completely or substantially free of a dopant.

Clause 17. The method and/or the micro-LED device according to any one of Clauses 1-16, wherein the gallium nitride support layer is deposited by an epitaxy process.

Clause 18. The method and/or the micro-LED device according to any one of Clauses 1-17, wherein the gallium nitride support layer has a thickness in a range from about 50 nm to about 5,000 nm, such as about 200 nm to about 3,000 nm.

Clause 19. The method and/or the micro-LED device according to any one of Clauses 1-18, wherein the n-doped gallium nitride layer comprises gallium nitride and one or more dopants selected from silicon, germanium, oxygen, or any combination thereof.

Clause 20. The method and/or the micro-LED device according to any one of Clauses 1-19, wherein the n-doped gallium nitride layer has a thickness in a range from about 500 nm to about 5,000 nm, such as about 1,500 nm to about 2,500 nm.

Clause 21. The method and/or the micro-LED device according to any one of Clauses 1-20, wherein the n-doped gallium nitride layer is deposited by an epitaxy process.

Clause 22. The method and/or the micro-LED device according to any one of Clauses 1-21, wherein the quantum well region comprises in a range from about 1 pair to about 5 pairs of the alternating layers of indium gallium nitride wells and gallium nitride barriers.

Clause 23. The method and/or the micro-LED device according to any one of Clauses 1-22, wherein the quantum well region layer has a thickness in a range from about 3 nm to about 50 nm, such as about 5 nm to about 20 nm.

Clause 24. The method and/or the micro-LED device according to any one of Clauses 1-23, wherein the alternating layers of indium gallium nitride wells and gallium nitride barriers are deposited by an epitaxy process.

Clause 25. The method and/or the micro-LED device according to any one of Clauses 1-24, wherein each of the indium gallium nitride well layers has a thickness in a range from about 2 nm to about 5 nm, such as about 2.7 nm to about 3 nm.

Clause 26. The method and/or the micro-LED device according to any one of Clauses 1-25, wherein each of the gallium nitride barrier layers has a thickness in a range from about 2 nm to about 5 nm, such as about 2.7 nm to about 3 nm.

Clause 27. The method and/or the micro-LED device according to any one of Clauses 1-26, wherein the p-doped gallium nitride layer comprises gallium nitride and one or more dopants selected from magnesium, beryllium, zinc, carbon, or any combination thereof.

Clause 28. The method and/or the micro-LED device according to any one of Clauses 1-27, wherein the p-doped gallium nitride layer has a thickness in a range from about 10 nm to about 400 nm, such as about 20 nm to about 250 nm.

Clause 29. The method and/or the micro-LED device according to any one of Clauses 1-28, wherein the p-doped gallium nitride layer is deposited by an epitaxy process.

Clause 30. The method and/or the micro-LED device according to any one of Clauses 1-29, wherein the first mesa structure has a size in a range from about 1 μm to about 10 μm.

Clause 31. The method and/or the micro-LED device according to any one of Clauses 1-30, wherein the first mesa etch process comprises exposing the first portion of the layered stack to photolithography and at least one of a reactive ion etch, a dry etch, a wet etch, or any combination thereof to form the first mesa structure.

Clause 32. The method and/or the micro-LED device according to any one of Clauses 1-31, wherein the first mesa structure comprises angled sides outwardly sloping from the p-doped gallium nitride layer to the n-doped gallium nitride layer.

Clause 33. The method and/or the micro-LED device according to any one of Clauses 1-32, wherein the TCO layer comprises indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof, and in some examples, the TCO layer comprises indium tin oxide.

Clause 34. The method and/or the micro-LED device according to any one of Clauses 1-33, wherein the TCO layer has a thickness in a range from about 10 nm to about 500 nm, such as about 10 nm to about 200 nm, about 10 nm to about 150 nm, or about 10 nm to about 120 nm.

Clause 35. The method and/or the micro-LED device according to any one of Clauses 1-34, wherein the TCO layer has a diameter in a range from about 1 μm to about 50 μm, such as about 1 μm to about 20 μm, about 1 μm to about 10 μm, about 1 μm to about 5 μm, or about 1 μm to about 3 μm.

Clause 36. The method and/or the micro-LED device according to any one of Clauses 1-35, wherein the TCO layer is deposited by a sputtering process, a PVD process, a CVD process, an ALD process, or any combination thereof.

Clause 37. The method and/or the micro-LED device according to any one of Clauses 1-36, wherein the second mesa etch process comprises exposing the lower portion of the n-doped gallium nitride layer and the gallium nitride support layer to photolithography and at least one of a reactive ion etch, a dry etch, a wet etch, or any combination thereof to form the second mesa structure.

Clause 38. The method and/or the micro-LED device according to any one of Clauses 1-37, wherein the second mesa structure has a size in a range from about 1 μm to about 10 μm.

Clause 39. The method and/or the micro-LED device according to any one of Clauses 1-38, wherein the dielectric passivation layer comprises one or more of aluminum oxide, silicon oxide, hafnium oxide, silicon nitride, silicon oxynitride, hafnium silicate, dopants thereof, or any combination thereof.

Clause 40. The method and/or the micro-LED device according to any one of Clauses 1-39, wherein the dielectric passivation layer has a thickness in a range from about 5 nm to about 150 nm.

Clause 41. The method and/or the micro-LED device according to any one of Clauses 1-40, wherein the dielectric passivation layer is deposited by a CVD process, a PE-CVD process, an ALD process, a PE-ALD process, or any combination thereof.

Clause 42. The method and/or the micro-LED device according to any one of Clauses 1-41, wherein revealing the portion of the TCO layer in the first mesa structure further comprises one or more photolithography, one or more etch processes, or any combination thereof.

Clause 43. The method and/or the micro-LED device according to any one of Clauses 1-42, wherein revealing the portion of the n-doped gallium nitride layer in the second mesa structure further comprises one or more photolithography, one or more etch processes, or any combination thereof.

### Clause Group 3 Containing the Following Clauses 1-42

Clause 1. A method for producing a micro-LED device, comprising: depositing a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; forming a first mesa structure from at least a first portion of the layered stack during a first mesa etch process, wherein at least the p-doped gallium nitride layer, the quantum well region, and an upper portion of the n-doped gallium nitride layer are etched away to form the first mesa structure; depositing a TCO layer on at least a portion of the p-doped gallium nitride layer during a TCO deposition process; forming a second mesa structure from at least a second portion of the layered stack during a second mesa etch process, wherein at least a lower portion of the n-doped gallium nitride layer and the gallium nitride support layer are etched away to form the second mesa structure; depositing a first dielectric passivation layer on the first and second mesa structures during a first passivation layer deposition process; revealing at least a portion of the TCO layer in the first mesa structure and at least a portion of the n-doped gallium nitride layer in the second mesa structure; depositing a p-contact layer on the revealed portion of the TCO layer and an n-contact layer on the revealed portion of the n-doped gallium nitride layer; depositing a second dielectric passivation layer on the first and second mesa structures during a second passivation layer deposition process; revealing at least a portion of the p-contact layer and at least a portion of the n-contact layer; and depositing a p-bonding pad on the revealed portion of the p-contact layer and a first portion of the second dielectric passivation layer and depositing an n-bonding pad on the revealed portion of the n-contact layer and a second portion of the second dielectric passivation layer.

Clause 2. A micro-LED device, comprising: a layered stack disposed on a substrate, wherein the layered stack comprises: a gallium nitride support layer disposed on the substrate; an n-doped gallium nitride layer disposed on the gallium nitride support layer; a quantum well region disposed on the n-doped gallium nitride layer, wherein the quantum well region comprises alternating layers of indium gallium nitride wells and gallium nitride barriers; and a p-doped gallium nitride layer disposed on the quantum well region; a first mesa structure comprising at least a first portion of the layered stack, wherein at least the p-doped gallium nitride layer, the quantum well region, and an upper portion of the n-doped gallium nitride layer form the first mesa structure; a TCO layer disposed on at least a portion of the p-doped gallium nitride layer; a second mesa structure comprising at least a second portion of the layered stack, wherein at least a lower portion of the n-doped gallium nitride layer and the gallium nitride support layer form the second mesa structure; a first dielectric passivation layer disposed on a first portion of the first mesa structure and a first portion of the second mesa structure; a revealed portion of the TCO layer in the first mesa structure is free or substantially free of the first dielectric passivation layer; a revealed portion of the n-doped gallium nitride layer in the second mesa structure is free or substantially free of the first dielectric passivation layer; a p-contact layer disposed on the revealed portion of the TCO layer and an n-contact layer disposed on the revealed portion of the n-doped gallium nitride layer; a second dielectric passivation layer disposed on the first and second mesa structures; a revealed portion of the p-contact layer in the first mesa structure is free or substantially free of the second dielectric passivation layer; a revealed portion of the n-contact layer in the second mesa structure is free or substantially free of the second dielectric passivation layer; a p-bonding pad disposed on the revealed portion of the p-contact layer and a first portion of the second dielectric passivation layer; and an n-bonding pad disposed on the revealed portion of the n-contact layer and a second portion of the second dielectric passivation layer.

Clause 3. The method and/or the micro-LED device according to Clause 1 or 2, wherein the p-contact layer has a circular geometry.

Clause 4. The method and/or the micro-LED device according to any one of Clauses 1-3, wherein the n-contact layer has a ring geometry at least partially encompasses the p-contact layer.

Clause 5. The method and/or the micro-LED device according to any one of Clauses 1-4, wherein the p-contact layer has a diameter in a range from about 1 μm to about 50 μm and a thickness in a range from about 100 nm to about 1 μm.

Clause 6. The method and/or the micro-LED device according to any one of Clauses 1-5, wherein the n-contact layer has a ring geometry, wherein the n-contact layer has a width in a range from about 1 μm to about 50 μm, a thickness in a range from about 100 nm to about 1 μm, and an outer diameter of the ring geometry in a range from about 10 μm to about 200 μm.

Clause 7. The method and/or the micro-LED device according to any one of Clauses 1-6, wherein each of the p-contact layer and the n-contact layer independently comprises a metal comprising titanium, nickel, aluminum, rhodium, platinum, silver, gold, copper, chromium, tungsten, alloys thereof, or any combination thereof.

Clause 8. The method and/or the micro-LED device according to any one of Clauses 1-7, wherein each of the p-contact layer and the n-contact layer independently comprises a metal stack, wherein each metal stack comprises three or more metal layers of different compositions, and wherein each metal layer comprises titanium, nickel, aluminum, rhodium, platinum, silver, gold, copper, chromium, tungsten, alloys thereof, or any combination thereof, and/or wherein some examples, each metal stack comprises Cr/Al/Ti/Ni/Au or Cr/Pt/Au.

Clause 9. The method and/or the micro-LED device according to any one of Clauses 1-8, wherein each of the p-contact layer and the n-contact layer is independently deposited by one or more of a sputtering process, a thermal evaporation process, an electron beam (e-beam) process, an electroplating process, a PVD process, a CVD process, a PE-CVD process, an ALD process, a PE-ALD process, or any combination thereof.

Clause 10. The method and/or the micro-LED device according to any one of Clauses 1-9, wherein each of the p-bonding pad and the n-bonding pad independently comprises a metal comprising titanium, nickel, aluminum, rhodium, platinum, silver, gold, copper, chromium, tungsten, alloys thereof, or any combination thereof.

Clause 11. The method and/or the micro-LED device according to any one of Clauses 1-10, wherein each of the p-bonding pad and the n-bonding pad is independently deposited by one or more of a sputtering process, a thermal evaporation process, an electron beam (e-beam) process, an electroplating process, a PVD process, a CVD process, a PE-CVD process, an ALD process, a PE-ALD process, or any combination thereof.

Clause 12. The method and/or the micro-LED device according to any one of Clauses 1-11, wherein the substrate comprises one or more of sapphire, silicon, silicon carbide, dopants thereof, or any combination thereof.

Clause 13. The method and/or the micro-LED device according to any one of Clauses 1-12, wherein the substrate has a thickness in a range from about 50 μm to about 500 μm, such as about 150 μm to about 200 μm.

Clause 14. The method and/or the micro-LED device according to any one of Clauses 1-13, wherein the gallium nitride support layer comprises gallium nitride having a purity in a range from about 95 at % to about 100 at %, and in some examples, undoped GaN.

Clause 15. The method and/or the micro-LED device according to any one of Clauses 1-14, wherein the gallium nitride support layer comprises gallium nitride and is completely or substantially free of a dopant.

Clause 16. The method and/or the micro-LED device according to any one of Clauses 1-15, wherein the gallium nitride support layer is deposited by an epitaxy process.

Clause 17. The method and/or the micro-LED device according to any one of Clauses 1-16, wherein the gallium nitride support layer has a thickness in a range from about 50 nm to about 5,000 nm, such as about 200 nm to about 3,000 nm.

Clause 18. The method and/or the micro-LED device according to any one of Clauses 1-17, wherein the n-doped gallium nitride layer comprises gallium nitride and one or more dopants selected from silicon, germanium, oxygen, or any combination thereof.

Clause 19. The method and/or the micro-LED device according to any one of Clauses 1-18, wherein the n-doped gallium nitride layer has a thickness in a range from about 500 nm to about 5,000 nm, such as about 1,500 nm to about 2,500 nm.

Clause 20. The method and/or the micro-LED device according to any one of Clauses 1-19, wherein the n-doped gallium nitride layer is deposited by an epitaxy process.

Clause 21. The method and/or the micro-LED device according to any one of Clauses 1-20, wherein the quantum well region comprises in a range from about 1 pair to about 5 pairs of the alternating layers of indium gallium nitride wells and gallium nitride barriers.

Clause 22. The method and/or the micro-LED device according to any one of Clauses 1-21, wherein the quantum well region layer has a thickness in a range from about 3 nm to about 50 nm, such as about 5 nm to about 20 nm.

Clause 23. The method and/or the micro-LED device according to any one of Clauses 1-22, wherein the alternating layers of indium gallium nitride wells and gallium nitride barriers are deposited by an epitaxy process.

Clause 24. The method and/or the micro-LED device according to any one of Clauses 1-23, wherein each of the indium gallium nitride well layers has a thickness in a range from about 2 nm to about 5 nm, such as about 2.7 nm to about 3 nm.

Clause 25. The method and/or the micro-LED device according to any one of Clauses 1-24, wherein each of the gallium nitride barrier layers has a thickness in a range from about 2 nm to about 5 nm, such as about 2.7 nm to about 3 nm.

Clause 26. The method and/or the micro-LED device according to any one of Clauses 1-25, wherein the p-doped gallium nitride layer comprises gallium nitride and one or more dopants selected from magnesium, beryllium, zinc, carbon, or any combination thereof.

Clause 27. The method and/or the micro-LED device according to any one of Clauses 1-26, wherein the p-doped gallium nitride layer has a thickness in a range from about 10 nm to about 400 nm, such as about 20 nm to about 250 nm.

Clause 28. The method and/or the micro-LED device according to any one of Clauses 1-27, wherein the p-doped gallium nitride layer is deposited by an epitaxy process.

Clause 29. The method and/or the micro-LED device according to any one of Clauses 1-28, wherein the first mesa structure has a size in a range from about 1 μm to about 10 μm.

Clause 30. The method and/or the micro-LED device according to any one of Clauses 1-29, wherein the first mesa etch process comprises exposing the first portion of the layered stack to photolithography and at least one of a reactive ion etch, a dry etch, a wet etch, or any combination thereof to form the first mesa structure.

Clause 31. The method and/or the micro-LED device according to any one of Clauses 1-30, wherein the first mesa structure comprises angled sides outwardly sloping from the p-doped gallium nitride layer to the n-doped gallium nitride layer.

Clause 32. The method and/or the micro-LED device according to any one of Clauses 1-31, wherein the TCO layer comprises indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof, and in some examples, the TCO layer comprises indium tin oxide.

Clause 33. The method and/or the micro-LED device according to any one of Clauses 1-32, wherein the TCO layer has a thickness in a range from about 10 nm to about 500 nm, such as about 10 nm to about 200 nm, about 10 nm to about 150 nm, or about 10 nm to about 120 nm.

Clause 34. The method and/or the micro-LED device according to any one of Clauses 1-33, wherein the TCO layer has a diameter in a range from about 1 μm to about 50 μm, such as about 1 μm to about 20 μm, about 1 μm to about 10 μm, about 1 μm to about 5 μm, or about 1 μm to about 3 μm.

Clause 35. The method and/or the micro-LED device according to any one of Clauses 1-34, wherein the TCO layer is deposited by a sputtering process, a PVD process, a CVD process, an ALD process, or any combination thereof.

Clause 36. The method and/or the micro-LED device according to any one of Clauses 1-35, wherein the second mesa etch process comprises exposing the lower portion of the n-doped gallium nitride layer and the gallium nitride support layer to photolithography and at least one of a reactive ion etch, a dry etch, a wet etch, or any combination thereof to form the second mesa structure.

Clause 37. The method and/or the micro-LED device according to any one of Clauses 1-36, wherein the second mesa structure has a size in a range from about 1 μm to about 10 μm.

Clause 38. The method and/or the micro-LED device according to any one of Clauses 1-37, wherein each of the first dielectric passivation layer and the second dielectric passivation layer independently comprises one or more of aluminum oxide, silicon oxide, hafnium oxide, silicon nitride, silicon oxynitride, hafnium silicate, dopants thereof, or any combination thereof.

Clause 39. The method and/or the micro-LED device according to any one of Clauses 1-38, wherein each of the first dielectric passivation layer and the second dielectric passivation layer independently has a thickness in a range from about 5 nm to about 150 nm.

Clause 40. The method and/or the micro-LED device according to any one of Clauses 1-39, wherein each of the first dielectric passivation layer and the second dielectric passivation layer independently is deposited by a CVD process, a PE-CVD process, an ALD process, a PE-ALD process, or any combination thereof.

Clause 41. The method and/or the micro-LED device according to any one of Clauses 1-40, wherein revealing the portion of the TCO layer in the first mesa structure further comprises one or more photolithography, one or more etch processes, or any combination thereof.

Clause 42. The method and/or the micro-LED device according to any one of Clauses 1-41, wherein revealing the portion of the n-doped gallium nitride layer in the second mesa structure further comprises one or more photolithography, one or more etch processes, or any combination thereof.

### Other Exemplary Embodiments May Be or Include

In one or more embodiments, the micro-LED die size (lateral dimensions) may be in the range of about 1 μm to about 3 μm and in some examples, up to about 10 μm, about 20 μm, or about 30 μm. The mesa size may be similar to the die size, or much smaller, from about 1 μm to about 3 μm and in some examples, up to about 10 μm, about 20 μm, or about 30 μm.

Metal contact may be formed in a full or half coaxial geometry, with the p-contact at the center, and the n-contact surrounding the p-contact. The p-contact may cover the whole mesa including the sidewall, or only on top of the top surface of the mesa (in some embodiments), or only cover the center portion of the mesa top surface (in some embodiments). The n-contact may be formed as a full ring shape, or may be a portion of ring to allow the wiring of the p-contact to bonding pad.

In one or more embodiments, a method, comprising: disposing at least one LED layer of a light emitting diode (LED) on a substrate; and forming a mesa in the at least one LED layer. Mesa size (about 3~5 μm or even smaller) may be much smaller than die size (about 10~50 μm). The mesa depth may be in a range from about 100 nm, about 200 nm, about 250 nm, about 300 nm, about 400 nm, about 500 nm to greater than 1 μm.

In one or more embodiments, a method, comprising: Depositing a transparent conductive oxide (TCO) layer on the mesa. The TCO layer size may be from 1~3 microns to up to tens of microns. The thickness of the TCO layer may be about 5 nm, about 10 nm, about 20 nm, about 30 nm, about 40 nm, about 50 nm, about 60 nm, about 70 nm, about 80 nm, about 90 nm, about 100 nm, about 120 nm, about 150 nm, or greater.

In one or more embodiments, a method, comprising: forming a body in the at least one LED layer (die isolation or singulation). In some examples, the body size (die size) may be from about 1 μm to about 3 μm and in some examples, up to about 10 μm, about 20 μm, or about 30 μm. The body size or body thickness is the thickness of the epitaxial layer or material on the substrate.

In one or more embodiments, a method may include: depositing a first passivation layer and patterning the passivation layer to form an n-contact opening and a p-contact opening. The first passivation layer may be or include aluminum oxide, silicon oxide, hafnium oxide, silicon nitride (e.g., Al₂O₃, SiO₂, HfO₂, SiN), oxides thereof, nitrides thereof, dopants thereof, or any combination thereof. In some examples, first passivation layer may be formed or otherwise deposited by ALD or PE-CVD, or other method, or a combination of more than one layer by more than one method. The thickness of the first passivation layer may be about 5 nm, about 10 nm, about 20 nm, about 30 nm, about 40 nm, about 50 nm, about 60 nm, about 70 nm, about 80 nm, about 90 nm, about 100 nm, about 120 nm, about 150 nm, or greater.

In one or more embodiments, a method may include depositing a conductive material stack, where the conductive material stack may be disposed in the n-contact opening to contact a LED layer form a n-contact; and the conductive material stack may be disposed in the p-contact opening to contact the TCO form a p-contact. In some embodiments, n-contacts may be formed in a full ring shape. In some embodiments, n-contacts may be formed in a partial ring shape or c-shaped, as shown in the Figures (e.g., FIG. 10E). In some embodiments, n-contacts may be on the top surface of n-GaN. In some embodiments, n-contacts may also cover the sidewall of the LED body. The p-contacts and the n-contacts may independently have a thickness in a range from about 100 nm, about 200 nm, about 250 nm, about 300 nm, about 400 nm, about 500 nm to greater than 1 μm. The p-contacts and the n-contacts may be independently formed by one single step of deposition and patterning, or by two steps of deposition and patterning.

In one or more embodiments, a method may include depositing a second passivation layer and patterning the passivation layer to form an n-bonding pad opening and a p-bonding pad opening. The first passivation layer may be or include Al₂O₃, SiO₂, HfO₂, SiN, dopants thereof, or any combination thereof, formed by ALD or PE-CVD, or other method, or a combination of more than one layer by more than one method. The thickness of the passivation layer may be in a range from about 5 nm, about 10 nm, about 20 nm, to about 30 nm, about 40 nm, about 50 nm, about 60 nm, about 70 nm, about 80 nm, about 90 nm, about 100 nm, about 120 nm, about 150 nm, or greater.

In one or more embodiments, a method may include depositing p- and n-bonding pads on the second passivation layer. The bonding pads may be in a rectangular shape, with a width of about 1 μm, about 2 μm, or about 3 μm and a length of about 10 μm, about 12 μm, about 15 μm, about 20 μm, or greater depending on the die size, and a thickness of a few hundreds of nm to about 1 μm or greater. The separation of bonding pads may be from about 1 μm, about 2 μm, or about 3 μm to about 10 μm, about 12 μm, about 15 μm, about 20 μm, or greater.

In some embodiments, a first passivation layer is formed, then p- and n-metal contacts are deposited to serve as both metal contacts and bonding pads. In some embodiments, a second passivation layer is formed on p- and n-metal contacts followed by bonding pad opening. The second passivation layer may avoid shorting in flip-chip bonding between p- and n-bonding pads which are deposited afterwards.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method for producing a micro-light emitting diode (LED) device, comprising:
depositing a layered stack disposed on a substrate, wherein the layered stack comprises:
a gallium nitride support layer disposed on the substrate;
an n-doped gallium nitride layer disposed on the gallium nitride support layer;
a quantum well region disposed on the n-doped gallium nitride layer, wherein the quantum well region comprises alternating layers of indium gallium nitride wells and gallium nitride barriers; and
a p-doped gallium nitride layer disposed on the quantum well region;
forming a first mesa structure from at least a first portion of the layered stack during a first mesa etch process, wherein at least the p-doped gallium nitride layer, the quantum well region, and an upper portion of the n-doped gallium nitride layer are etched away to form the first mesa structure;
depositing a transparent conductive oxide (TCO) layer on at least a portion of the p-doped gallium nitride layer during a TCO deposition process;
forming a second mesa structure from at least a second portion of the layered stack during a second mesa etch process, wherein at least a lower portion of the n-doped gallium nitride layer and the gallium nitride support layer are etched away to form the second mesa structure;
depositing a dielectric passivation layer on the first and second mesa structures during a passivation layer deposition process;
revealing at least a portion of the TCO layer in the first mesa structure to form a revealed portion of the TCO layer and revealing at least a portion of the n-doped gallium nitride layer in the second mesa structure to form a revealed portion of the n-doped gallium nitride layer; and
depositing a p-contact layer on the revealed portion of the TCO layer and an n-contact layer on the revealed portion of the n-doped gallium nitride layer.

2. The method of claim 1, wherein the p-contact layer has a circular geometry, the n-contact layer has a ring geometry, and the n-contact layer is coaxial to and encompasses the p-contact layer.

3. The method of claim 1, wherein the p-contact layer has a diameter in a range from about 1 μm to about 50 μm and a thickness in a range from about 100 nm to about 1 μm.

4. The method of claim 1, wherein the n-contact layer has a ring geometry, wherein the n-contact layer has a width in a range from about 1 μm to about 50 μm, a thickness in a range from about 100 nm to about 1 μm, and an outer diameter of the ring geometry in a range from about 10 μm to about 200 μm.

5. The method of claim 1, wherein each of the p-contact layer and the n-contact layer independently comprises a metal stack, wherein each metal stack comprises three or more metal layers of different compositions, and wherein each metal layer comprises titanium, nickel, aluminum, rhodium, platinum, silver, gold, copper, chromium, tungsten, alloys thereof, or any combination thereof.

6. The method of claim 1, wherein the substrate comprises one or more of sapphire, silicon, silicon carbide, dopants thereof, or any combination thereof, and wherein the substrate has a thickness in a range from about 50 μm to about 500 μm.

7. The method of claim 1, wherein the gallium nitride support layer comprises gallium nitride and is completely or substantially free of a dopant, and wherein the gallium nitride support layer has a thickness in a range from about 50 nm to about 5,000 nm.

8. The method of claim 1, wherein the n-doped gallium nitride layer comprises gallium nitride and one or more dopants selected from silicon, germanium, oxygen, or any combination thereof, and wherein the n-doped gallium nitride layer has a thickness in a range from about 500 nm to about 5,000 nm.

9. The method of claim 1, wherein the quantum well region comprises in a range from about 1 pair to about 5 pairs of the alternating layers of indium gallium nitride wells and gallium nitride barriers, wherein the quantum well region layer has a thickness in a range from about 3 nm to about 50 nm, and wherein each of the indium gallium nitride well layers has a thickness in a range from about 2 nm to about 5 nm.

10. The method of claim 1, wherein each of the gallium nitride barrier layers has a thickness in a range from about 2 nm to about 5 nm.

11. The method of claim 1, wherein the p-doped gallium nitride layer comprises gallium nitride and one or more dopants selected from magnesium, beryllium, zinc, carbon, or any combination thereof, and wherein the p-doped gallium nitride layer has a thickness in a range from about 10 nm to about 400 nm.

12. The method of claim 1, wherein the first mesa etch process comprises exposing the first portion of the layered stack to photolithography and at least one of a reactive ion etch, a dry etch, a wet etch, or any combination thereof to form the first mesa structure.

13. The method of claim 1, wherein the first mesa structure comprises angled sides outwardly sloping from the p-doped gallium nitride layer to the n-doped gallium nitride layer.

14. The method of claim 1, wherein the TCO layer comprises indium tin oxide (ITO), aluminum-doped zinc oxide (AZO), fluorine-doped tin oxide (FTO), indium zinc oxide (IZO), tin oxide, indium oxide, zinc oxide, dopants thereof, or any combination thereof, wherein the TCO layer has a thickness in a range from about 10 nm to about 500 nm, and wherein the TCO layer has a diameter in a range from about 1 μm to about 50 μm.

15. The method of claim 1, wherein the second mesa etch process comprises exposing the lower portion of the n-doped gallium nitride layer and the gallium nitride support layer to photolithography and at least one of a reactive ion etch, a dry etch, a wet etch, or any combination thereof to form the second mesa structure.

16. The method of claim 1, wherein the dielectric passivation layer comprises one or more of aluminum oxide, silicon oxide, hafnium oxide, silicon nitride, silicon oxynitride, hafnium silicate, dopants thereof, or any combination thereof, and wherein the dielectric passivation layer has a thickness in a range from about 5 nm to about 150 nm.

17. The method of claim 1, wherein revealing the portion of the TCO layer in the first mesa structure further comprises one or more photolithography, one or more etch processes, or any combination thereof.

18. The method of claim 1, wherein revealing the portion of the n-doped gallium nitride layer in the second mesa structure further comprises one or more photolithography, one or more etch processes, or any combination thereof.

19. A method for producing a micro-light emitting diode (LED) device, comprising:
depositing a layered stack disposed on a substrate, wherein the layered stack comprises:
a gallium nitride support layer disposed on the substrate;
an n-doped gallium nitride layer disposed on the gallium nitride support layer;
a quantum well region disposed on the n-doped gallium nitride layer, wherein the quantum well region comprises alternating layers of indium gallium nitride wells and gallium nitride barriers; and
a p-doped gallium nitride layer disposed on the quantum well region;
forming a first mesa structure from at least a first portion of the layered stack during a first mesa etch process, wherein at least the p-doped gallium nitride layer, the quantum well region, and an upper portion of the n-doped gallium nitride layer are etched away to form the first mesa structure;
depositing a transparent conductive oxide (TCO) layer on at least a portion of the p-doped gallium nitride layer during a TCO deposition process;
forming a second mesa structure from at least a second portion of the layered stack during a second mesa etch process, wherein at least a lower portion of the n-doped gallium nitride layer and the gallium nitride support layer are etched away to form the second mesa structure;
depositing a first dielectric passivation layer on the first and second mesa structures during a first passivation layer deposition process;
revealing at least a portion of the TCO layer in the first mesa structure and at least a portion of the n-doped gallium nitride layer in the second mesa structure;
depositing a p-contact layer on the revealed portion of the TCO layer and an n-contact layer on the revealed portion of the n-doped gallium nitride layer;
depositing a second dielectric passivation layer on the first and second mesa structures during a second passivation layer deposition process;
revealing at least a portion of the p-contact layer and at least a portion of the n-contact layer; and
depositing a p-bonding pad on the revealed portion of the p-contact layer and a first portion of the second dielectric passivation layer and depositing an n-bonding pad on the revealed portion of the n-contact layer and a second portion of the second dielectric passivation layer.

20. A micro-light emitting diode (LED) device, comprising:
a layered stack disposed on a substrate, wherein the layered stack comprises:
a gallium nitride support layer disposed on the substrate;
an n-doped gallium nitride layer disposed on the gallium nitride support layer;
a quantum well region disposed on the n-doped gallium nitride layer, wherein the quantum well region comprises alternating layers of indium gallium nitride wells and gallium nitride barriers; and
a p-doped gallium nitride layer disposed on the quantum well region;
a first mesa structure comprising at least a first portion of the layered stack, wherein at least the p-doped gallium nitride layer, the quantum well region, and an upper portion of the n-doped gallium nitride layer form the first mesa structure;
a transparent conductive oxide (TCO) layer disposed on at least a portion of the p-doped gallium nitride layer;
a second mesa structure comprising at least a second portion of the layered stack, wherein at least a lower portion of the n-doped gallium nitride layer and the gallium nitride support layer form the second mesa structure;
a dielectric passivation layer disposed on a first portion of the first mesa structure and a first portion of the second mesa structure;
a revealed portion of the TCO layer in the first mesa structure is free or substantially free of the dielectric passivation layer;
a revealed portion of the n-doped gallium nitride layer in the second mesa structure is free or substantially free of the dielectric passivation layer; and
a p-contact layer disposed on the revealed portion of the TCO layer and an n-contact layer disposed on the revealed portion of the n-doped gallium nitride layer.
